(19) United States
(12) Patent Application Publication
(10) Pub. No.: US 2012/0013836 A1
(43) Pub. Date: Jan. 19, 2012

(54) LIQUID CRYSTAL DISPLAY APPARATUS AND MANUFACTURING METHOD THEREOF

(76) Inventors: Yuko Teraoka, Osaka (JP); Isamu Miyake, Osaka (JP); Shinichi Terashita, Osaka (JP); Koichi Miyachi, Osaka (JP)

(21) Appl. No.: 13/256,774

(22) PCT Filed: Mar. 3, 2010
(86) PCT No.: PCT/JP2010/053453

§ 371 Date: Sep. 15, 2011

(30) Foreign Application Priority Data
Mar. 17, 2009 (JP) 2009-064799

(51) Int. Cl. G02F 1/1337; H01L 33/08

(52) U.S. Cl. 349/124; 438/30; 257/E33.012

(57) ABSTRACT

The present invention provides a liquid crystal display device that has good reliability and can inhibit an image sticking phenomenon even when a comparatively low temperature is set for baking the alignment layer, and a method for manufacturing such a liquid crystal display device. The liquid crystal display device of the prevent invention includes a configuration in which a liquid crystal layer including liquid crystal molecules is sandwiched between a pair of substrates, and includes an alignment layer on a surface of at least one of the substrates on the liquid crystal layer side thereof. The alignment layer is obtained by performing an aligning treatment by light irradiation on a layer formed using an alignment layer material including a first constituent material and a second constituent material. The first constituent material demonstrates a property of controlling the alignment of the liquid crystal molecules under light irradiation. The second constituent material is a polymer which has no property of controlling the alignment of the liquid crystal molecules, and at least part of which is imidized.

### TECHNICAL FIELD

The present invention relates to a liquid crystal display device and a method for manufacturing same. More specifically, the present invention relates to a liquid crystal display device suitable for flat displays such as portable information terminals, personal computers, word processors, amusement devices, teaching devices, and television sets which are used by a vast number of people and also display panels, display windows, display doors, and display walls using a liquid crystal shutter effect, and relates a method for manufacturing such a liquid crystal display device.

### BACKGROUND ART

Liquid crystal display devices are presently widely used in personal computers, television sets, word processors, and the like, as display devices featuring thin profile and light weight. From the standpoint of display characteristics of liquid crystal display devices, the liquid crystal material used and also the alignment layer serving to uniformly align the liquid crystals are important.

In particular, as the liquid crystal display devices have been recently increasing in size, it became important to treat the alignment layer uniformly and with good efficiency. Further, the transition to more accurate liquid crystal display devices is accompanied by the so-called image sticking phenomenon according to which a residual image remains on the display surface, and an alignment layer in which charge accumulation is unlikely to occur is strongly needed to inhibit such a phenomenon.

In a liquid crystal display device in which liquid crystal aligning treatment has been performed unidirectionally within the substrate plane, as in the TN (Twisted Nematic) mode, ECB (Electrically Controlled Birefringence) mode, and VATN (Vertical Alignment Twisted Nematic) mode, the display characteristics vary significantly depending on the observation direction. For this reason, the direction in which the image sticking phenomenon can be observed is restricted not only to the front direction, but also to the direction depending on display characteristics of the liquid crystal alignment mode. In liquid crystal TV and large-screen displays for information, domain division of liquid crystals is performed for viewing angle compensation during white display. Therefore, in a domain division mode in which viewing angle compensation has been performed, the image sticking phenomenon is seen uniformly in all orientations and therefore it is mandatory to prevent the image sticking phenomenon.

Liquid crystal aligning treatment agents including a polyimide precursor and a solvent-soluble polyimide resin have been developed as a technique for improving the charge accumulation characteristic of the alignment layer (see, for example, Patent Documents 1 and 2).

Further, a variety of methods for performing the aligning treatment of the alignment layer (photoalignment layer) by irradiation with light such as polarized ultraviolet radiation, that is, photoalignment methods, have been suggested. The photoalignment methods excel in uniformity of liquid crystal alignment and operability, but are insufficient in terms of characteristics such as the image sticking phenomenon.

The photoalignment method is an alignment method by which an alignment controlling force is generated in the alignment layer and/or the alignment control direction of the alignment layer is changed by irradiating (exposing) the alignment layer with light such as polarized ultraviolet radiation.

A method by which a resin system including a polyamic acid and a soluble polyimide is used as a liquid crystal aligning agent and the resin system is coated on the substrate and then irradiated with polarized ultraviolet radiation, thereby forming a liquid crystal alignment layer that excels in uniformity and operability and demonstrates small accumulation of residual electric charges when used as a liquid crystal display element has been disclosed as a technique relating to the photoalignment method (see, for example, Patent Document 3).
Patent Document 1: Japanese Patent Application Laid-open No. H8-220541
Patent Document 2: Japanese Patent Application Laid-open No. H10-197875
Patent Document 3: Japanese Patent Application Laid-open No. 2004-264354

### DISCLOSURE OF THE INVENTION

However, with the techniques described in Patent Documents 1 and 2, where a low baking temperature of the alignment layer is set, the charge accumulation characteristic of the alignment layer cannot be sufficiently improved.

The inventors have investigated the problems associated with the conventional methods for improving the residual DC and voltage retention ratio, such as described in Patent Documents 1 and 2. The results obtained will be explained below in detail with reference to FIG. 17.

Alignment layer materials in which a material (a polyamic acid or a polyimide with a low imidization ratio) for improving the electric characteristics of the alignment layer is mixed with a material (a polyimide with a high imidization ratio) of the alignment layer have been used to improve the electric characteristics of the alignment layer. Further, the alignment layer has been formed by coating the alignment layer material on the substrate and then baking. During coating and baking, the polyimide with a high imidization ratio and the polyamic acid are separated into two layers. Further, as shown in FIG. 17, an alignment layer 110 having a stacked structure of an electric characteristic improving layer (lower layer) 101 formed from a polyamic acid and an alignment layer (upper layer) 102 formed from a polyimide with a high imidization ratio is formed on a substrate 112. Thus, the conventional relationship between the imidization ratios of the upper layer and lower layer is such that the imidization ratio of the upper layer is usually higher than that of the lower layer.

Such two-layer separation into the upper layer and lower layer proceeds during coating and baking, that is, occurs naturally due to a difference in polarity between the layers. When the alignment layer material of a mixed system is thus used, a difference in imidization ratio between the materials is provided and the difference in polarity between the materials is induced thereby separating the upper layer and lower layer.

However, with the conventional techniques, where low-temperature baking is performed, the imidization ratio of the electric characteristic improving layer 101 for electric characteristic improvement sometimes increases insufficiently and the reliability improvement effect is not demonstrated.

With the technique described in Patent Document 3, a high baking temperature should be also set for the alignment layer in order to obtain the adequate imidization ratio, and a sufficient effect cannot be demonstrated in low-temperature burning.

The present invention has been created with the foregoing in view and it is an object thereof to provide a liquid crystal display device that has good reliability and can inhibit an image sticking phenomenon even when the temperature during alignment layer baking is set to a comparatively low temperature, and a method for manufacturing such a liquid crystal display device.

The inventors have conducted a comprehensive study of liquid crystal display devices that have good reliability and can inhibit an image sticking phenomenon even when the baking temperature of the alignment layer is set to a comparatively low temperature, and focused their attention on the feature of using an alignment layer material of a mixed system. Thus, it has been discovered that good reliability can be demonstrated and the image sticking phenomenon can be inhibited, even when the baking temperature of the alignment layer is set to a comparatively low temperature, by performing the alignment treatment with light irradiation of a layer formed by using an alignment layer material including a first constituent material demonstrating a property of controlling the alignment of liquid crystal molecules under light irradiation and a polymer (second constituent material) that does not have a property of controlling the alignment of liquid crystal molecules and is at least partially imidized. Based on this discovery, the inventors conceived of the possibility of resolving the above-described problems and created the present invention.

Thus, the present invention provides a liquid crystal display device including a configuration in which a liquid crystal layer including liquid crystal molecules is sandwiched between a pair of substrates, and including an alignment layer on a surface of at least one substrate of the pair of substrates on the liquid crystal layer side thereof, wherein the alignment layer is obtained by performing an aligning treatment by light irradiation on a layer formed using an alignment layer material including a first constituent material and a second constituent material; the first constituent material demonstrates a property of controlling the alignment of the liquid crystal molecules under light irradiation; the second constituent material is a polymer having no property of controlling the alignment of the liquid crystal molecules; and at least part of the polymer is imidized.

The configuration of the liquid crystal display device in accordance with the present invention is not particularly restricted by other constituent elements, provided that the configuration is formed using the aforementioned constituent elements as necessary elements.

The present invention also provides a method for manufacturing a liquid crystal display device including a configuration in which a liquid crystal layer including liquid crystal molecules is sandwiched between a pair of substrates, and including an alignment layer on a surface of at least one substrate of the pair of substrates on the liquid crystal layer side thereof, the method including the steps of: forming a layer on the at least one substrate by using an alignment layer material including a first constituent material and a second constituent material; and forming the alignment layer by performing an aligning treatment on the layer by light irradiation, wherein the first constituent material demonstrates a property of controlling the alignment of the liquid crystal molecules under light irradiation; the second constituent material is a polymer having no property of controlling the alignment of the liquid crystal molecules; and at least part of the polymer is imidized. Also according to this method, it is possible to exhibit good reliability and inhibit an image sticking phenomenon even when the temperature during alignment layer baking is set to a comparatively low temperature.

The process for manufacturing a liquid crystal display device in accordance with the present invention is not particularly restricted by other process steps, provided that the above-described steps are included as necessary steps.

The preferred embodiments of the liquid crystal display device and the manufacturing method thereof in accordance with the present invention will be described below in greater detail. The below-described embodiments may be combined as appropriate.

It is preferred that the first constituent material be a polymer and an imidization ratio of the first constituent material be less than an imidization ratio of the second constituent material.

It is preferred that the first constituent material be a polymer including a side chain and the side chain include a photofunctional group.

It is preferred that the alignment layer be a vertical alignment layer that controls vertical alignment of the liquid crystal molecules.

It is preferred that the alignment layer control the alignment of the liquid crystal molecules so that an average pretilt angle of the liquid crystal layer is equal to or greater than 87°.

It is preferred that the alignment layer control the alignment of the liquid crystal molecules so that an average pretilt angle of the liquid crystal layer is equal to or less than 89.5°.

It is preferred that the side chain include at least one photofunctional group selected from the group consisting of a coumarins group, a cinnamate group, a chalcone group, an azobenzene group, and a stilbene group.

It is preferred that the ratio of the second constituent material to a sum total of the first constituent material and the second constituent material be equal to or greater than 40 wt. % and equal to or less than 95 wt. %.

It is preferred that the first constituent material appear on the surface of the at least one substrate after the alignment layer material is coated on the at least one substrate.

It is preferred that the alignment layer include a laminated structure of an upper layer formed using the first constituent material and a lower layer formed using the second constituent material.

### EFFECTS OF THE INVENTION

With the liquid crystal display device and the manufacturing method thereof in accordance with the present invention, good reliability can be ensured and the image sticking phenomenon can be inhibited even when the baking temperature of the alignment layer is set to a comparatively low temperature.

### BRIEF DESCRIPTION OF THE DRAWINGS

FIG. 1 is a cross-sectional schematic view illustrating the configuration of the liquid crystal display device according to Embodiment 1.

FIG. 2 shows a basic structure of the first constituent material in the alignment layer material according to Embodiment 1; in FIG. 2, the portion surrounded by a solid line is a unit (acid anhydride unit) derived from an acid anhydride, and a portion surrounded by a broken line is a unit (diamine unit) derived from a diamine.

FIG. 3 shows another structure of the first constituent material in the alignment layer material according to Embodiment 1; in FIG. 3, the portion surrounded by a solid line is a unit (acid anhydride unit) derived from an acid anhydride, a portion surrounded by a broken line is a unit (photoaligning diamine unit) derived from a diamine used for the photoalignment layer, that is, a diamine that has a side chain 21 having a photofunctional group, and a portion surrounded by a dash-dot line is a unit (non-photoaligning diamine unit) derived from a diamine that has a side chain 22 having no photofunctional group.

FIG. 4 is a cross-sectional schematic diagram of the alignment layer in the liquid crystal display device according to Embodiment 1 that shows a state in which the alignment layer is coated on a glass substrate provided with ITO; FIG. 4(a) shows a state after pre-baking, FIG. 4(b) shows a state in which the treatment is conducted at a baking temperature of 100 to 130° C., and FIG. 4(c) shows a state obtained by performing the baking treatment at a temperature of 180 to 200° C.

FIG. 5 is a graph illustrating the film thickness before and after the baking treatment when the alignment layer is subjected to baking treatment at various temperatures.

FIG. 6 is a perspective schematic drawing illustrating the relationship between the photoalignment treatment direction and pretilt direction in Embodiment 1.

FIG. 7(a) is a plan schematic drawing illustrating the direction of a liquid crystal director in one pixel (or one sub-pixel) and the photoalignment treatment direction with respect to a pair of substrates (upper and lower substrates) in the case in which the liquid crystal display device according to Embodiment 1 has a monodomain; FIG. 7(b) is a schematic diagram illustrating the absorption axis direction of the polarizer provided in the liquid crystal display device shown in FIG. 7(a); FIG. 7(a) also shows the state in which the photoalignment treatment directions are orthogonal between the pair of substrates and an AC voltage equal to or higher than a threshold is applied between the pair of substrates; in FIG. 7(a), the solid line arrow shows the light irradiation direction (photoalignment treatment direction) of the lower substrate, and a dot line arrow shows the light irradiation direction (photoalignment treatment direction) of the upper substrate.

FIG. 8(a) is a plan schematic drawing illustrating the direction of a liquid crystal director in one pixel (or one sub-pixel) and the photoalignment treatment direction with respect to a pair of substrates (upper and lower substrates) in the case in which the liquid crystal display device according to Embodiment 1 has a monodomain; FIG. 8(b) is a schematic diagram illustrating the absorption axis direction of the polarizer provided in the liquid crystal display device shown in FIG. 8(a); FIG. 8(a) also shows the state in which the photoalignment treatment directions are counter parallel between the pair of substrates and an AC voltage equal to or higher than a threshold is applied between the pair of substrates; in FIG. 8(a), the solid line arrow shows the light irradiation direction (photoalignment treatment direction) of the lower substrate, and a dot line arrow shows the light irradiation direction (photoalignment treatment direction) of the upper substrate.

FIG. 9 is a cross-sectional schematic diagram illustrating the first positional relationship between the substrate and the photomask in the photoalignment treatment process according to Embodiment 1 for performing domain division by the proximity exposure method using an alignment mask.

FIG. 10 is a cross-sectional schematic diagram illustrating the second positional relationship between the substrate and the photomask in the photoalignment treatment process according to Embodiment 1 for performing domain division by the proximity exposure method using an alignment mask.

FIG. 11(a) is a plan schematic view illustrating the direction of the average liquid crystal director in one pixel (or one sub-pixel), the photoalignment treatment direction with respect to the pair of substrates (upper and lower substrates), and the domain division pattern in the case in which the liquid crystal display device 4 according to Embodiment 1 has four domains; FIG. 11(b) is a schematic diagram illustrating the absorption axis direction of the polarizer provided in the liquid crystal display device shown in FIG. 11(a); FIG. 11(a) also shows the state in which an AC voltage equal to or higher than a threshold is applied between the pair of substrates; in FIG. 11(a), the solid line arrow shows the light irradiation direction (photoalignment treatment direction) of the lower substrate (drive element substrate), and the dot line arrow shows the light irradiation direction (photoalignment treatment direction) of the upper substrate (color filter substrate).

FIG. 12(a) is a plan schematic view illustrating the direction of the average liquid crystal director in one pixel (or one sub-pixel), the photoalignment treatment direction with respect to the pair of substrates (upper and lower substrates), and the domain division pattern in the case in which the liquid crystal display device according to Embodiment 1 has four domains; FIG. 12(b) is a schematic diagram illustrating the absorption axis direction of the polarizer provided in the liquid crystal display device shown in FIG. 12(a); FIG. 12(c) is a cross-sectional schematic view taken along the A-B line in FIG. 12(a) when an AC voltage equal to or higher than a threshold is applied between the pair of substrates, and shows the alignment direction of the liquid crystal molecules; in FIG. 12(a), the dot line arrow shows the light irradiation direction (photoalignment treatment direction) of the lower substrate (drive element substrate), and the solid line arrow shows the light irradiation direction (photoalignment treatment direction) of the upper substrate (color filter substrate); In FIG. 12(c), the dot line shows the boundary between the domains.

FIG. 13 is a plan schematic view showing a transparent electrode in the evaluation cell (liquid crystal display device) used in the AC image sticking evaluation test.

FIG. 14 is a plan schematic view showing a display state during conduction in the evaluation cell (liquid crystal display device) for the AC image sticking evaluation test.

FIG. 15 is a plan schematic view showing a display state in the evaluation cell (liquid crystal display device) during the AC image sticking evaluation test.

FIG. 16 is a side schematic view showing the positional relationship between the ND filter and the evaluation cell (liquid crystal display device) in the AC image sticking evaluation test.

FIG. 17 is a cross-sectional schematic view illustrating the liquid crystal display device according to Comparative Example 1.

### MODES FOR CARRYING OUT THE INVENTION

In the present description, the VATN mode may be also called the RTN (reverse twist TN; vertical alignment TN) mode.

In the description, the ECB mode may be of a type (VAECB) that has vertical alignment when no voltage is applied and horizontal alignment during voltage application, and of a type that has horizontal alignment when no voltage is applied and vertical alignment during voltage application.

In the description, the photofunctional group is not particularly limited provided that it is a functional group demonstrating the property of controlling the alignment of liquid crystal molecules under light irradiation, but the preferred group can demonstrate at least one from among a crosslinking reaction (inclusive of a dimerization reaction), a decomposition reaction, an isomerization reaction, and photorealignment, more preferably at least one from among a crosslinking reaction (inclusive of a dimerization reaction), an isomerization reaction, and photorealignment under irradiation with light, preferably ultraviolet radiation and more preferably polarized ultraviolet radiation.

In the description, the expression “controlling the alignment uniformly” does not mean that the alignment is necessarily controlled uniformly in the strict sense of the word, and the alignment may be uniform to a degree at which a single liquid crystal mode can be realized.

In the description, the expression “liquid crystal molecules are controlled to a vertical alignment” does not mean that the alignment of liquid crystal molecules is necessarily controlled in the direction strictly perpendicular to the alignment layer surface, and the alignment of liquid crystal molecules may be aligned in the direction that is orthogonal to the alignment layer surface to a degree at which a vertical alignment mode such as a VATN mode can be realized.

In the description, the expression “alignment control directions are in the same direction” does not mean that the alignment control directions are necessarily in the same direction in the strict sense of the word, and the alignment control directions may be in the same direction to a degree at which a single liquid crystal mode can be realized.

In the description, the average pretilt angle of the liquid crystal layer is an angle formed by the substrate surface and the direction (polar angle direction) of an average profile (director) of liquid crystal molecules in the perpendicular direction of the liquid crystal layer in the state in which no voltage is applied between the pair of substrates (liquid crystal layer). The device for measuring the average pretilt angle of the liquid crystal layer is not particularly limited, and for example a commercially available tilt angle measuring device (produced by Shintec Inc., trade name: OptiPro) can be used. In this tilt angle measuring device, the substrate surface is taken at 0°, the direction orthogonal to the substrate surface is taken at 90°, and the average profile of liquid crystal molecules in the perpendicular direction of the liquid crystal layer is taken as the pretilt angle. Therefore, this device is advantageous for measuring the average pretilt angle of the liquid crystal layer. The profile of liquid crystal molecules in the vicinity (interface) of the alignment layer is a factor determining the average pretilt angle of the liquid crystal layer, and the liquid crystal molecules at the interface are thought to induce elastic deformation in the liquid crystal molecules in the bulk (central layer) of the liquid crystal layer. Since the profile of liquid crystal molecules in the vicinity (interface) of the alignment layer is different from that in the bulk (central layer) of the liquid crystal layer, the directions (polar angle directions) of profiles of liquid crystal molecules at the interface and in the central layer are thought to be strictly speaking different.

The embodiments of the present invention will be described below in greater detail with reference to the appended drawings, but the present invention is not limited to these embodiments.

### Embodiment 1

The liquid crystal display device according to the present embodiment has a configuration in which a liquid crystal layer including liquid crystal molecules is sandwiched between a pair of substrates, and has an alignment layer on a surface of at least one substrate of the pair of substrates on the liquid crystal layer side thereof. The alignment layer is obtained by performing an aligning treatment by light irradiation on a layer formed using an alignment layer material including a first constituent material and a second constituent material. The first constituent material demonstrates a property of controlling the alignment of the liquid crystal molecules under light irradiation. The second constituent material is a polymer having no property of controlling the alignment of the liquid crystal molecules. At least part of the polymer is imidized.

The liquid crystal display device according to the present embodiment is manufactured by a step of forming the layer on the at least one substrate by using the alignment layer material including the first constituent material and the second constituent material, and a step of forming the alignment layer by performing an aligning treatment on the layer by light irradiation.

As a result, it is possible to form an alignment layer in which the adequate imidization ratio is maintained not only at the usual baking temperature, but also in low-temperature baking, and good reliability can be demonstrated regardless of the baking temperature. Further, it is possible to obtain a liquid crystal display device that also has excellent display characteristics such that the occurrence of image sticking phenomenon caused by residual DC and image sticking caused by the AC mode (can be also referred to hereinbelow as AC image sticking) is unlikely.

The liquid crystal display device according to the present embodiment will be described below in greater detail.

The liquid crystal display device according to the present embodiment may be a liquid crystal display device of a simple matrix type, but a liquid crystal display device of an active matrix type is preferred. Thus, it is preferred that the liquid crystal display device according to the present embodiment have pixels arranged in a matrix-like configuration and constituted by pixel electrodes arranged in a matrix-like configuration on one substrate at the liquid crystal layer side thereof and a common electrode disposed on the other substrate at the liquid crystal layer side thereof.

From the standpoint of improving the display quality and responsiveness of the liquid crystal display device, it is preferred that the alignment layer be provided on the surfaces of both substrates on the liquid crystal layer sides thereof.

From the standpoint of further reducing image sticking, it is preferred that in the liquid crystal display device according to the present embodiment the alignment layer obtained by performing an aligning treatment by light irradiation on the layer formed by using the alignment layer material including the first constituent material and the second constituent material be provided on the surfaces of both substrates on the liquid crystal layer sides thereof.

The alignment layer is obtained by performing an aligning treatment by light irradiation on the layer formed by using the alignment layer material including the first constituent material and the second constituent material, the first constituent material demonstrates a property of controlling the alignment of the liquid crystal molecules under light irradiation, the second constituent material is a polymer having no property of controlling the alignment of the liquid crystal molecules, and at least part of the polymer is imidized. As a result, the above-mentioned effects can be demonstrated and a liquid crystal display device having excellent display quality can be realized even though the aligning treatment of the alignment layer has been performed by light irradiation. Further, merits of the photoalignment method as a manufacturing process can be enjoyed. In addition, coatability of the alignment layer material can be improved.

For example, merits of the photoalignment method include the possibility of inhibiting the occurrence of contamination and dust in the aligning treatment by performing the aligning treatment in a contactless manner, the possibility of inhibiting the occurrence of display defects (for example, rubbing streaks) in the mechanical aligning treatment such as rubbing, and the possibility of facilitating the division of pixels into a plurality of domains having the desired design (flat shape) by exposing the alignment layer by using a photomask having formed therein light-transmitting portions having the desired pattern.

The alignment layer is subjected to aligning treatment by light irradiation (preferably irradiation with ultraviolet radiation, more preferably polarized ultraviolet radiation). Therefore, it is preferred that the alignment layer be sensitive to light, preferably ultraviolet radiation (in particular, polarized ultraviolet radiation). More specifically, it is preferred that the alignment layer react with light, preferably ultraviolet radiation at a lower exposure energy and within a shorter time interval.

The first constituent material is not particularly limited, provided that it can demonstrate a property of controlling the alignment of the liquid crystal molecules under light irradiation, and may be an organic material or an inorganic material. Organic materials are preferred, and among them polymers are especially preferred.

When the first constituent material is a polymer, the molecular weight thereof is not particularly limited, but a molecular weight that makes is possible to use the polymer in the alignment layer, similarly to the polymers contained in the conventional alignment layer materials, is preferred.

The second constituent material is a polymer that has been imidized at least partially, that is, a polyimide (inclusive of a partial polyimide).

The molecular weight of the second constituent material (polymer) is not particularly limited, but a molecular weight that makes is possible to use the polymer in the alignment layer, similarly to the polymers contained in the conventional alignment layer materials, is preferred.

It is preferred that the first constituent material be a polymer and that the imidization ratio of the first constituent material be less than the imidization ratio of the second constituent material. In this case, the polymer type of the first constituent material is not particularly limited, but a polyamic acid (polyimide precursor) or a polyimide (inclusive of a partial polyimide) is preferred.

The imidization ratio of the first constituent material is preferably equal to or less than 70%, more preferably equal to or less than 50%, and even more preferably equal to or less than 35%. The imidization ratio above 70% can increase the residual DC voltage, cause the image sticking phenomenon, and degrade the display quality.

A polyamic acid can be advantageously used as the first constituent material, and the lower limit of the imidization ratio of the first constituent material is not limited.

The imidization ratio of the second constituent material is preferably equal to or higher than 5%, more preferably equal to or higher than 15%, even more preferably equal to or higher than 30%. Where the imidization ratio is less than 5%, the voltage retention ratio can decrease, spots and unevenness can occur, and the display quality can decrease.

The imidization ratio of the second constituent material is preferably equal to or less than 95%, more preferably equal to or less than 80%, and even more preferably equal to or less than 70%. Where the imidization ratio is above 95%, the second constituent material can be exposed together with the first constituent material on the alignment layer surface, and the second constituent material can hinder the alignment control performed by the first constituent material. Further, the residual DC Voltage can increase, the image sticking phenomenon can occur, and the display quality can be degraded.

It is preferred that the first constituent material have photofunctional groups as a means for demonstrating a property of controlling the alignment of liquid crystal molecules under light irradiation. Thus, it is preferred that the first constituent material be a polymer that has a side chain having a photofunctional group in at least part thereof. As a result, the liquid crystal display device according to the present embodiment can be realized easier and the effect of the present invention can be demonstrated more effectively.

It is preferred that the first constituent material be a polymer having as necessary structural units a first structural unit that demonstrates a property of controlling the alignment of the liquid crystal molecules under light irradiation and a second structural unit that demonstrates a property of controlling the alignment of the liquid crystal molecules regardless of light irradiation. As a result, the degree of AC image sticking can be reduced and a liquid crystal display device having better display quality can be realized.

The distribution of the first structural units and second structural units is not particularly limited, and the copolymer may be an alternate copolymer, a block copolymer, a random copolymer, and a graft copolymer.

Photofunctional groups are preferred and among them photofunctional groups contained in the side chain of the first structural units are especially preferred as a means for demonstrating a property of controlling the alignment of liquid crystal molecules in the first structural units under light irradiation. As a result, the liquid crystal display device according to the present embodiment can be realized easier and the AC image sticking can be effectively reduced, Thus, the first structural unit preferably has a photofunctional group, more preferably has a side chain having a photofunctional group.

Aligning functional groups are preferred and among them aligning functional groups contained in the side chain of the second structural unit are more preferred as a means for demonstrating a property of controlling the alignment of liquid crystal molecules in the second structural unit regardless of light irradiation. As a result, the liquid crystal display device according to the present embodiment can be realized easier and the AC image sticking can be effectively reduced. Thus, the second structural unit preferably has an aligning functional group, more preferably has a side chain having an aligning functional group.

The aligning functional groups are not particularly limited, provided that a property of controlling the alignment of liquid crystal molecules can be demonstrated regardless of light irradiation, and the conventional well-known aligning functional groups, for example, vertically aligning functional groups and horizontally aligning functional groups can be used.

The vertically aligning functional groups are not particularly limited, provided that a property of controlling the vertical alignment of liquid crystal molecules can be demonstrated, but functional groups that demonstrate a property of controlling the vertical alignment of liquid crystal molecules, without a treatment or after rubbing, preferably without a treatment, that is, even without the aligning treatment, are preferred.

The horizontally aligning functional groups are not particularly limited, provided that a property of controlling the horizontal alignment of liquid crystal molecules can be demonstrated, but functional groups that demonstrate a property of controlling the horizontal alignment of liquid crystal molecules, without a treatment or after rubbing, are preferred.

Thus, the liquid crystal display device according to the present embodiment may have a configuration in which a liquid crystal layer including liquid crystal molecules is sandwiched between a pair of substrates, and may have an alignment layer on a surface of at least one substrate of the pair of substrates on the liquid crystal layer side thereof, wherein the alignment layer is obtained by performing an aligning treatment by light irradiation on a layer formed using an alignment layer material including a polymer having as necessary structural units a structural unit which has a photofunctional group and by which the alignment direction of liquid crystal molecules in the alignment layer surface is controlled by light irradiation of the alignment layer and a structural unit which has an aligning functional group and by which the alignment direction of liquid crystal molecules in the alignment layer surface is controlled regardless of light irradiation of the alignment layer.

The necessary structural units (first structural unit and second structural unit) preferably have the same alignment control direction. As a result, the liquid crystal display device according to the present embodiment can be effectively driven in a single liquid crystal mode such as a VATN mode, a TN mode, an ECB mode, or an IPS (In-Place Switching) mode.

From a similar standpoint, it is preferred that the alignment layer perform uniform alignment control of liquid crystal molecules in the alignment layer plane.

From the standpoint of effectively driving the liquid crystal display device according to the present embodiment in the vertical alignment mode such as VATN mode, it is preferred that the alignment layer be a vertical alignment layer that performs vertical alignment control of liquid crystal molecules.

More specifically, when the liquid crystal display device according to the present embodiment is effectively driven in the vertical alignment mode such as VATN mode, the alignment layer preferably controls the alignment of liquid crystal molecules so that the average pretilt angle of the liquid crystal layer is 87 to 89.5°, more preferably 87.5 to 89°. As a result, a liquid crystal display device with a VATN mode that excels in a view angle characteristic, responsiveness, and light transmittance can be realized.

More specifically, from the standpoint of producing no adverse effect on contrast in the VATN mode (causing no increase in black brightness), it is preferred that the alignment layer control the alignment of liquid crystal molecules so that the average pretilt angle of the liquid crystal layer is equal to or higher than 87°, more preferably equal to or higher than 87.5°.

From the standpoint of inhibiting a residual image occurring when a pressure is applied to the display surface, that is, the so-called pressure-induced residual image, and confining the light quenching position within ±5° when the absorption axis of the cross Nicol polarizer is rotated through 45° and a voltage of 7.5 V is applied to the liquid crystal layer, it is preferred that the alignment layer control the alignment of liquid crystal molecules so that the average pretilt angle of the liquid crystal layer is equal to or less than 89.5°, more preferably equal to or less than 89°.

When the liquid crystal display device according to the present embodiment is effectively driven in a vertical alignment mode such as a VATN mode, the second structural unit preferably has a side chain having a vertically aligning functional group. As a result, it is possible to realize easily a liquid crystal display device of a vertical alignment mode such as a VATN mode.

From the standpoint of effectively driving the liquid crystal display device according to the present embodiment in the VATN mode, stabilizing the average pretilt angle of the liquid crystal layer at 87 to 89.5°, which is preferred for the VATN mode, and better inhibiting the AC image sticking, the following features (a) to (f) are preferred.

(a) The first constituent material is preferably a polymer that has a side chain having at least one photofunctional group selected from the group consisting of a coumarin group, a cinnamate group, a chalcone group, an azobenzene group, and a stilbene group, at least in part thereof. Likewise, the first structural unit preferably has a side chain having at least one photofunctional group selected from the group consisting of a coumarin group, a cinnamate group, a chalcone group, an azobenzene group, and a stilbene group.

(b) The first constituent material is preferably a polymer that has a side chain having a steroid skeleton. Likewise, the second structural unit preferably has a side chain having a steroid skeleton.

(c) The first constituent material may be a polymer that has a side chain having a structure in which three or four rings selected from 1,4-cyclohexylene and 1,4-phenylene are bonded linearly directly or by 1,2-ethylene. Thus, the first constituent material may be a polymer that has a side chain having a structure in which three or four rings are bonded linearly. The three or four rings may be selected, independently from each other, from 1,4-cyclohexylene and 1,4-phenylene, and the three or four rings may be bonded, independently from each other, by single bonds or 1,2-ethylene. Likewise, the second structural unit may have a side chain having a structure in which three or four rings selected from 1,4-cyclohexylene and 1,4-phenylene are bonded linearly directly or by 1,2-ethylene. Thus, the second structural unit may have a side chain having a structure in which three or four rings are bonded linearly. The three or four rings may be selected, independently from each other, from 1,4-cyclohexylene and 1,4-phenylene, and the three or four rings may be bonded, independently from each other, by single bonds or 1,2-ethylene.

(c′) It is more preferred that the first constituent material be a polymer that has a side chain having a structure in which three or four rings are bonded linearly, two end rings from among the three or four rings be 1,4-phenylene, one or two rings on the main chain side among the three or four rings be selected, independently from each other, from 1,4-cyclohexylene and 1,4-phenylene, and the bonds between the three or four rings be single bonds. Likewise, it is more preferred that the second structural unit have a side chain having a structure in which three or four rings are bonded linearly, two end rings from among the three or four rings be 1,4-phenylene, one or two rings on the main chain side among the three or four rings be selected, independently from each other, from 1,4-cyclohexylene and 1,4-phenylene, and the bonds between the three or four rings be single bonds.

(d) The first constituent material is preferably a polymer having at least one main chain structure selected from the group consisting of a polyamic acid (polyimide precursor), a polyimide, a polyamide, and a polysiloxane, more preferably a polymer having a main chain structure of a polyamic acid and/or a polyimide.

(e) The first constituent material is preferably a polymer formed using at least a diamine. Likewise the necessary structural unit is preferably formed by a diamine.

(f) The first constituent material is preferably a copolymer of a monomer component including a diamine and at least one of an acid anhydride and a dicarboxylic acid.

Further, the first constituent material may be a polymer having a main chain structure of a polyamidoimide. From the standpoint of improving heat resistance and electric characteristics of the alignment layer, it is more preferred that the first constituent material be a polymer having a main chain structure of at least either of a polyamic acid and a polyimide. Thus, it is more preferred that the first constituent material be a copolymer of a monomer component including a diamine and an acid anhydride.

From the standpoint of suppressing the AC image sticking more effectively, it is preferred that the weight ratio, % (introduction ratio), of the monomer component of the second structural unit to the monomer component of the first structural unit be 4 to 40%. From the standpoint of further increasing the average pretilt angle of the liquid crystal layer in the VATN mode, while suppressing the AC image persistency more effectively, it is preferred that the weight ratio, %, of the monomer component of the second structural unit to the monomer component of the first structural unit be equal to or greater than 4%. Further, from the standpoint of further increasing the average pretilt angle of the liquid crystal layer in the VATN mode while inhibiting the AC image sticking more effectively, it is preferred that the weight ratio, %, of the monomer component of the second structural unit to the monomer component of the first structural unit be equal to or less than 40%.

The second constituent material is introduced to improve electric characteristics of the liquid crystal display device. Thus, the second constituent material is used to inhibit image sticking (image sticking caused by residual DC) caused by charge accumulation in the liquid crystal display device. Therefore, when the content ratio of the second constituent material is small, the effect of improving the electric characteristics can be insufficient. Conversely, when the content ratio of the second constituent material is high, a stable alignment characteristic produced by the first constituent material cannot be obtained. As a result, optical characteristics inherent to a liquid crystal panel cannot be obtained.

More specifically, the ratio of the second constituent material to the sum total of the first constituent material and the second constituent material is preferably 40 wt. % to 95 wt. %, more preferably 45 wt. % to 90 wt. %, even more preferably 50 wt. % to 85 wt. %. Thus, the lower limit of the ratio is preferably equal to or greater than 40 wt. %, more preferably equal to or greater than 45 wt. %, and even more preferably equal to or greater than 50 wt. %, and the upper limit of the ratio is preferably equal to or less than 95 wt. %, more preferably equal to or less than 90 wt. %, and even more preferably equal to or less than 85 wt. %. Where the ratio is less than 40 wt. %, the voltage retention ratio of the alignment layer can decrease and the residual DC can increase. Where the ratio is higher than 95 wt. %, the AC image sticking can occur.

It is preferred that the first constituent material appear on the surface after the first constituent material and the second constituent material have been coated on the pair of substrates. Thus, it is preferred that the first constituent material appear on the surface of at least one substrate after the alignment layer material is coated on at least one substrate. As a result, the alignment property and electric characteristics of the alignment layer can be demonstrated more effectively.

The alignment layer preferably has a laminated structure of an upper layer (layer on the liquid crystal layer side) formed using the first constituent material and a lower layer (layer on the substrate side) formed using the second constituent material. As a result, the alignment property and electric characteristics of the alignment layer can be also demonstrated more effectively.

The liquid crystal display device preferably has pixels disposed in a matrix-like configuration including pixel electrodes disposed in a matrix-like configuration on the liquid crystal layer side of one substrate and a common electrode disposed on the liquid crystal layer side of the other substrate, and the pixels have two or more domains disposed adjacently to each other. With such a configuration, the boundaries of adjacent domains are often exposed in the overlapping state and the AC image sticking tends to increase in the portions that are exposed in the overlapping state (double-exposed portions). Further, the pretilt angle of liquid crystal molecules tend to spread in the double-exposed portions. However, by using the alignment layer according to the present embodiment in such a configuration, it is possible to widen the viewing angle, while effectively suppressing the AC image sticking and spread of pretilt angle of liquid crystal molecules in the double-exposed portions. From the standpoint of realizing the winding of viewing angle in the four directions (for example, up, down, right, left), it is preferred that the pixel has four domains.

Thus, in the liquid crystal display device, it is preferred that domain division be performed by dividing each pixel region for exposure (light irradiation). The VATN mode and ECB mode are advantageous as liquid crystal modes with domain division, and among them the VATN mode is preferred.

The above-described various features can be combined as appropriate.

The liquid crystal display device according to the present embodiment will be explained below in greater detail with reference to the appended drawings in the following sequence of issues: 1. Configuration Example of the Liquid Crystal Display Device; 2. Alignment Layer Material; 3. Method for Fabricating the Alignment Layer; and 4. Basic Operation of the Liquid Crystal Display Device.

The VATN mode will be described below in greater detail, but the present invention can be also applied to the TN mode, IPS mode, and ECB mode of horizontal alignment type. When the present invention is applied to the mode of a horizontal alignment type, it is possible to use, for example, a copolymer of a structural unit (for example, a diamine) in which a vertically aligning functional group is not introduced in a side chain or a structural unit (for example, a diamine) in which a hydrophilic functional group or horizontally aligning functional group is introduced in the side chain and a structural unit (for example, a diamine) having a photofunctional group of a horizontal alignment type.

(1. Configuration Example of the Liquid Crystal Display Device)

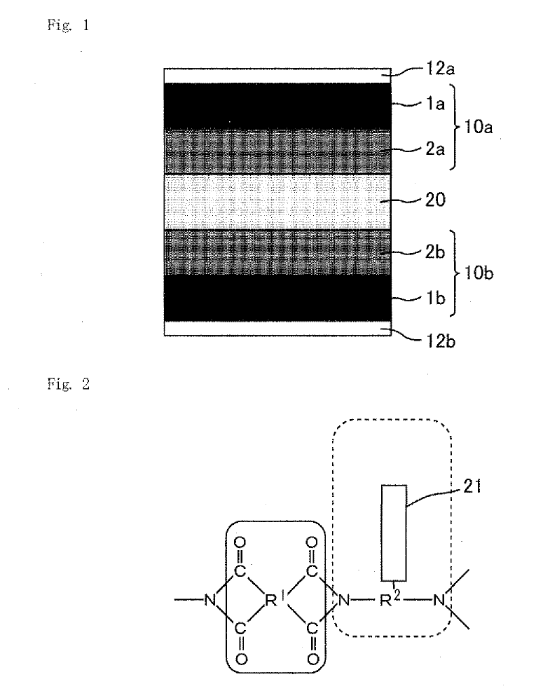

The advantageous configuration example of the liquid crystal display device according to the present embodiment is shown in FIG. 1. Thus, as shown in FIG. 1, in the liquid crystal display device according to the present embodiment, a liquid crystal layer 20 including a nematic liquid crystal molecule with negative dielectric constant anisotropy is sandwiched between a pair of substrates (upper and lower substrates) 12a, 12b.

The substrates 12a, 12b have insulating transparent substrates composed of glass or the like. Transparent electrodes are formed on the surfaces of the substrates 12a, 12b on the liquid crystal layer 20 side, and alignment layers 10a, 10b demonstrating vertical alignment ability are formed on the respective transparent electrodes. Further, one of the substrates 12a, 12b functions as a drive element substrate (for example, a TFT substrate) on which a drive element (switching element) is formed for each single pixel (or sup-pixel), and the other of the substrates 12a, 12b functions as a color filter substrate (CF substrate) on which a color filter is formed correspondingly to each pixel (or sub-pixel) of the drive element substrate. Thus, in the liquid crystal display device according to the present embodiment, one of the substrates 12a, 12b is the color filter substrate and the other one is the drive element substrate. In the drive element substrate, the transparent electrodes are connected to the drive elements and formed in a matrix-like configuration. These transparent electrodes function as pixel electrodes. In the color filter substrate, the transparent electrode is uniformly formed over the entire surface of the display region and functions as a common electrode. Further, on the surfaces of the substrates 12a, 12b on the sides opposite those facing the liquid crystal layer 20, polarizers are disposed, for example, in a cross Nicol configuration, and a cell thickness retaining body (spacer) for maintaining a constant cell thickness is disposed at a predetermined position (for example, a non-display region) between the substrates 12a, 12b.

The drive element substrate can be obtained by successively forming (1) scanning signal lines, (2) drive elements such as TFT, (3) data signal lines, and (4) pixel electrodes constituted by transparent electrodes on the glass substrate, thereby arranging the scanning signal lines and data signal lines on the glass substrate perpendicular to each other in a grating-like configuration, with an insulating layer being interposed therebetween, and disposing the drive elements and pixel electrodes at each crossing point.

The color filter substrate can be obtained by successively forming (1) a black matrix (BM), (2) color filters, (3) a protective film, and (4) a common electrode constituted by a transparent electrode on a glass substrate, thereby arranging the BM on the substrate in a grating-like configuration and disposing color filters in the regions compartmentalized by the BM.

The materials of the substrates 12a, 12b and transparent electrodes and also the material of the liquid crystal molecule are not particularly limited.

The alignment layers 10a, 10b have electric characteristic improving layers (second constituent portions) 1a, 1b and vertical photoalignment layers (first constituent portions) 2a, 2b provided from the substrate 12a, 12b sides in the order of description. The electric characteristic improving layers 1a, 1b, which are lower layers, are polymer layers for improving electric characteristics of the alignment layers 10a, 10b. For these layers, active alignment control of liquid crystal molecules is not required. These layers can inhibit the occurrence of image sticking caused by charge accumulation (image sticking caused by the residual DC). The electric characteristic improving layers 1a, 1b are formed by the second constituent material and preferably formed from a polyimide with a high imidization ratio. By using a polyimide with a high imidization ratio as the material (second constituent material) of the electric characteristic improving layers 1a, 1b, it is possible to inhibit the image sticking caused by the residual DC and also obtain a panel with excellent display performance. More specifically, a panel can be obtained in which the occurrence of spotting and unevenness is unlikely.

The vertical photoalignment layers 2a, 2b, which are upper layers, demonstrate, under light irradiation, the property of controlling the alignment of liquid crystal molecules, in particular aligning the liquid crystal molecules in a substantially orthogonal direction. With these layers, the alignment of the liquid crystal molecules can be controlled. The vertical photoalignment layers 2a, 2b are formed from the first constituent material and preferably formed from a polyamic acid or a polyimide with a low imidization ratio.

Thus, although the relationship between the imidization ratios of the upper layers and lower layers satisfies the following condition (imidization ratio of the upper layer)≦(imidization ratio of the lower layer), by separating the alignment layers 10a, 10b into two layers each, it is possible to provide an alignment layer on the front surface and obtain the desired alignment characteristic.

Film thickness of the alignment layers 10a, 10b is not particularly limited, but the preferred thickness is 10 to 200 nm (more preferably 20 to 180 nm, even more preferably 50 to 130 nm). Where the film thickness is less than 10 nm, the alignment control of liquid crystal molecules can be impossible. Where the film thickness is greater than 200 nm, the decrease in effective voltage applied to the liquid crystal layer 20 and/or degradation of residual DC voltage can occur. Furthermore, a uniform film can be difficult to obtain.

The film thickness of the electric characteristic improving layers 1a, 1b is not particularly limited, but this film thickness is preferably 10 to 150 nm (more preferably 20 to 135 nm, even more preferably 30 to 120 nm). Where the film thickness is less than 10 nm, the image sticking effect can occur. Where the film thickness is greater than 150 nm, a uniform film can be difficult to obtain.

The film thickness of the vertical photoalignment layers 2a, 2b is not particularly limited, but this film thickness is preferably 5 to 120 nm (more preferably 7 to 100 nm, even more preferably 10 to 80 nm). Where the film thickness is less than 5 nm, the alignment control can be incomplete. Where the film thickness is greater than 120 nm, the image sticking effect can easily occur.

(2. Alignment Layer Material)

The especially preferred alignment layer material according to the present embodiment will be described method.

The alignment layer material according to the present embodiment preferably includes as the necessary constituent materials a first constituent material demonstrating a characteristic of controlling the alignment of liquid crystal molecules under light irradiation and a second constituent material that does not actively controls the alignment of liquid crystal molecules, regardless of the light irradiation. The first constituent material and the second constituent material are both polymers, and the first constituent material has a side chain having a photofunctional group demonstrating vertical alignment ability.

In the alignment layers 10a, 10b obtained by performing an aligning treatment by light irradiation with respect to the films formed by using the alignment layer material according to the present embodiment, the alignment of liquid crystal molecules can be uniformly controlled (uniformly to a degree such that the VATN mode can be realized) within the plane of the alignment layers 10a, 10b. The alignment layers 10a, 10b are vertical alignment layers in which the alignment of liquid crystal molecules is controlled in the direction substantially orthogonal to the surface of the alignment layers 10a, 10b. It is preferred that the alignment of liquid crystal molecules be controlled so that the average pretilt angle of the liquid crystal layer 20 be 87 to 89.5°, more preferably 87.5 to 89°.

The polymer (first constituent material and second constituent material) in the alignment layer material according to the present embodiment includes a diamine as a necessary structural unit. Thus, the first alignment layer material according to the present embodiment and the second alignment layer material according to the present embodiment include a diamine as a monomer component of a necessary structural unit.

More specifically, the first constituent material and the second constituent material are each a copolymer of monomer components including a diamine and an acid anhydride, and the polymers in the alignment layer material according to the present embodiment have at least two different main chain structures of a polyamic acid and a polyimide. Thus, a polyamic acid or a polyimide with a low imidization ratio is used as the first constituent material, and a polyimide with a high imidization ratio that is higher than the imidization ratio of the first constituent material is used for the second constituent material. The polyimide with a high imidization ratio may have a completely imidized main chain or a partially imidized main chain.

By using such an alignment layer material according to the present embodiment, it is possible to drive effectively the liquid crystal display device according to the present embodiment in the VATN mode and stabilize the average pretilt angle of the liquid crystal layer 20 at 87 to 89.5°, which is advantageous for the VATN mode, Further, image sticking is also effective suppressed.

(2-1. First Constituent Material)

The first constituent material will be described below in greater detail with reference to FIG. 2.

When the alignment layers 10a, 10b are photoalignment layers, the first constituent material is a polyamic acid or a polyimide in which acid anhydride units and diamine units (first structural units, photoaligning diamine units) having a side chain 21 having a photofunctional group demonstrating vertical alignment ability are disposed alternately, as shown in FIG. 2.

No all of the diamine units are necessarily photoaligning diamine units. Thus, the diamine units may include not only the photoaligning diamine units, but also diamine units (second structural units, non-photoaligning diamine units) having a side chain 22 that has no photofunctional group. In this case, the first constituent material is a polyamic acid or a polyimide in which acid anhydride units and either photoaligning diamine units (first structural units) or non-photoaligning diamine units (second structural units) are arranged alternately.

The non-photoaligning diamine unit (second structural unit) may be a diamine unit (non-aligning diamine unit) that does not by itself have alignment ability such as vertical alignment ability, but preferably has the alignment ability identical to that of the photoaligning diamine units. Thus, the non-photoaligning diamine unit is preferably a unit (vertically aligning diamine unit) derived from a diamine for use in the vertical alignment layer, that is, a diamine that has a side chain having a vertically aligning functional group.

Thus, the first constituent material according to the present embodiment preferably includes a diamine that has a side chain having a photofunctional group in at least some of diamine units.

The photoaligning diamine unit has at least one photofunctional group selected from the group consisting of a cinnamate group (Formula (1) below), a chalcone group (Formula (2) below), an azobenzene group (Formula (3) below), a stilbene group (Formula (4) below), a cinnamoyl group, and a coumarins group. These photofunctional groups generate under light irradiation a crosslinking reaction (inclusive of a dimerization reaction), isomerization, photorealignment, or a combined reaction thereof and have a function of controlling the alignment of liquid crystal molecules in the alignment layer surface in the desired direction according to conditions of light irradiation such as irradiation angle. Coumarine derivatives include compounds represented by Formula (5) below. Among them, it is preferred that the first structural unit have in a side chain at least one photofunctional group selected from the group consisting of a cinnamate group (absorption wavelength (λmax) 270 nm), a chalcone group (absorption wavelength (λmax) 300 nm), an azobenzene group (absorption wavelength (λmax) 350 nm), and a stilbene group (absorption wavelength (λmax) 295 nm). As a result, the liquid crystal display device according to the present embodiment can be effectively driven in the VATN mode and the average pretilt angle of the liquid crystal layer can be stabilized at 87 to 89.5° (more preferably 87.5 to 89°) which is preferred for the VATN mode. Further, such photofunctional groups are also effective in terms of inhibiting the AC image sticking. These photofunctional groups may be used individually or in combinations of two or more thereof.

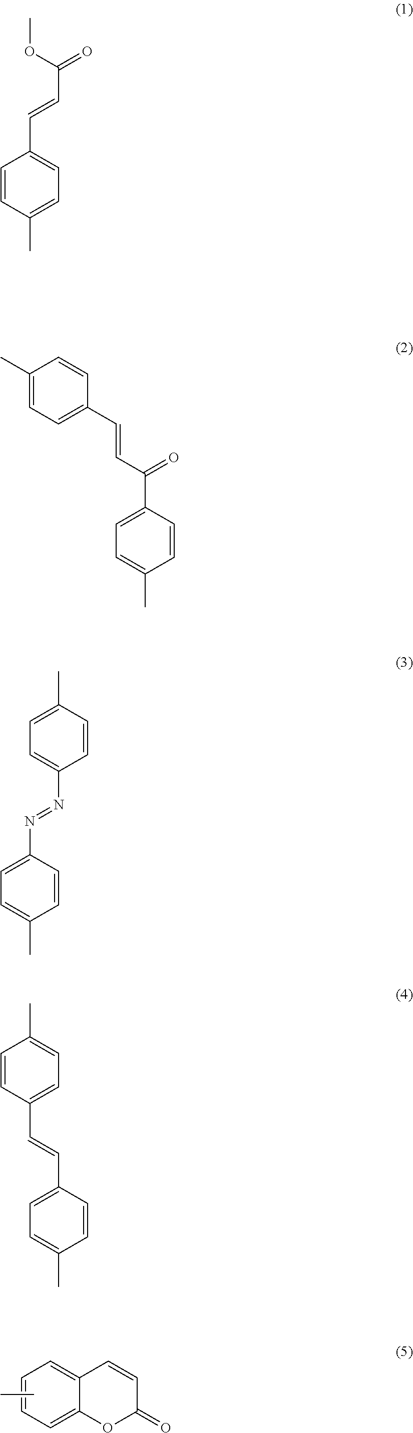

The vertically aligning diamine unit may include a vertically aligning functional group included in the conventional vertical alignment layers, but among them the units formed by diamines represented by Formula (7), Formula (8), and Formula (9) below are preferred. These diamines may be used individually or in combinations of two or more thereof.

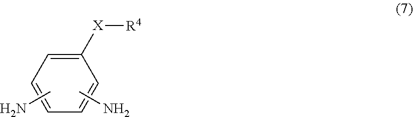

(In Formula (7), X is a single bond, —O—, —CO—, —COO—, —OCO—, —NHCO—, —CONH—, —S—, or an arylene group, R⁴ is an alkyl group having 10 to 20 carbon atoms, a monovalent organic group with an alicyclic skeleton having 4 to 40 carbon atoms, or a monovalent organic group having 6 to 20 carbon atoms and a fluorine atom).

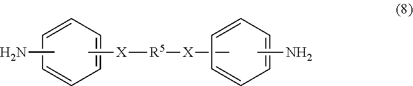

(In Formula (8), X is a single bond, —O—, —CO—, —COO—, —OCO—, —NHCO—, —CONH—, —S—, or an arylene group, R⁵ is a divalent organic group with an alicyclic skeleton having 4 to 40 carbon atoms).

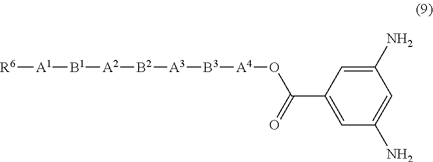

(In Formula (9), A¹, A², and A³ are, independently from one another, 1,4-cyclohexylene or 1,4-phenylene; A⁴ is 1,4-cyclohexylene, 1,4-phenylene, or a single bond; B¹, B², and B³ are, independently from one another, a single bond or 1,2-ethylene; R⁶ is an alkyl having 1 to 20 carbon atoms; one —CH₂— in the alkyl may be substituted with —O—).

In Formula (7), examples of the alkyl group having 10 to 20 carbon atoms that is represented by R⁴ include an n-decyl group, an n-dodecyl group, an n-pentadecyl group, an n-hexadecyl group, an n-octadecyl group, and an n-eicosyl group.

Examples of the organic group having an alicyclic skeleton with 4 to 40 carbon atoms that is represented by R⁴ in Formula (7) above and R⁵ in Formula (8) above include groups having an alicyclic skeleton derived from a cycloalkane such as cyclobutane, cyclopentane, cyclohexane, and cyclodecane, groups having a steroid skeleton such as cholesterol and cholestanol, and groups having a bridged alicyclic skeleton such as norbornene and adamantane. Among them, the groups having a steroid skeleton are especially preferred. The organic group having the alicyclic skeleton may be a group substituted with a halogen atom, preferably a fluorine atom, and a fluoroalkyl group, preferably a trifluoromethyl group.

Further, the example of the group having 6 to 20 carbon atoms and a fluorine atom that is represented by R⁴ in Formula (7) above include linear alkyl groups having six or more carbon atoms, such as an n-hexyl group, an n-octyl group, and an n-decyl group; alicyclic hydrocarbon groups having six or more carbon atoms, such as a cyclohexyl group and a cyclooctyl group; and groups obtained by substituting some or all of the hydrogen atoms in the organic groups such as aromatic hydrocarbon groups having six or more carbon atoms, such as a phenyl group and biphenyl group, with a fluorine atom or a fluoroalkyl group such as a trifluoromethyl group.

X in Formula (7) above and Formula (8) above is a single bond, —O—, —CO—, —COO—, —OCO—, —NHCO—, —CONH—, —S—, or an arylene group. Examples of the arylene group include a phenylene group, a trylene group, a biphenylene group, and a naphthylene group. Among them, groups represented by —O—, —COO—, and —OCO— are especially preferred.

Specific examples of the preferred diamines having the groups represented by Formula (7) above include dodecanoxy-2,4-diaminobenzene, pentadecanoxy-2,4-diaminobenzene, hexadecanoxy-2,4,-diaminobenzene, octadecanoxy-2,4-diaminobenzene, and compounds represented by Formulas (10) to (15) below.

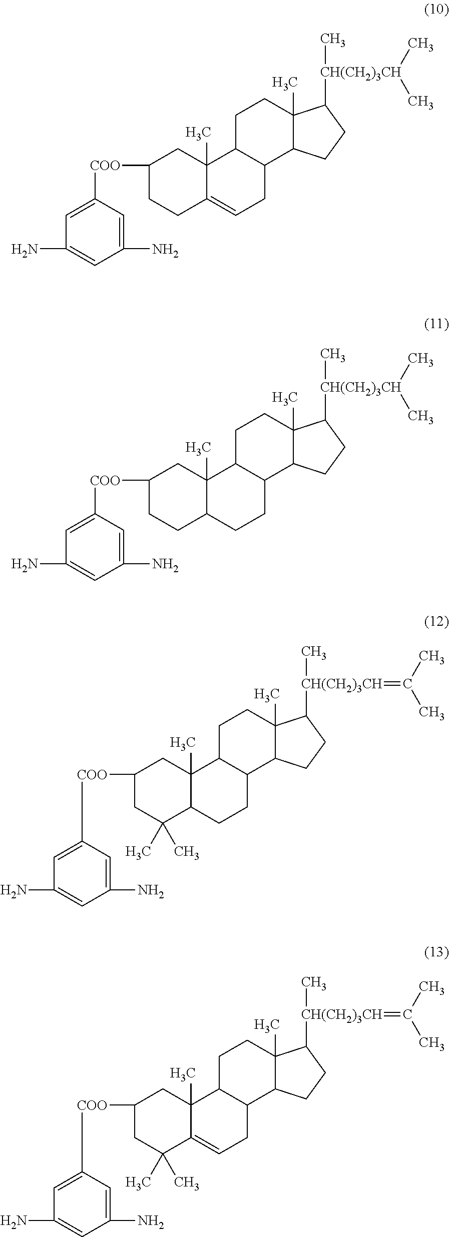

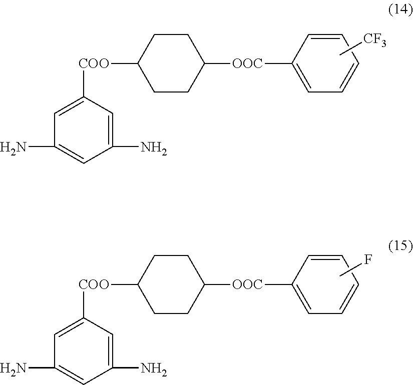

Further, specific examples of the preferred diamines having the groups represented by Formula (8) above include diamines represented by Formulas (16) to (18) below.

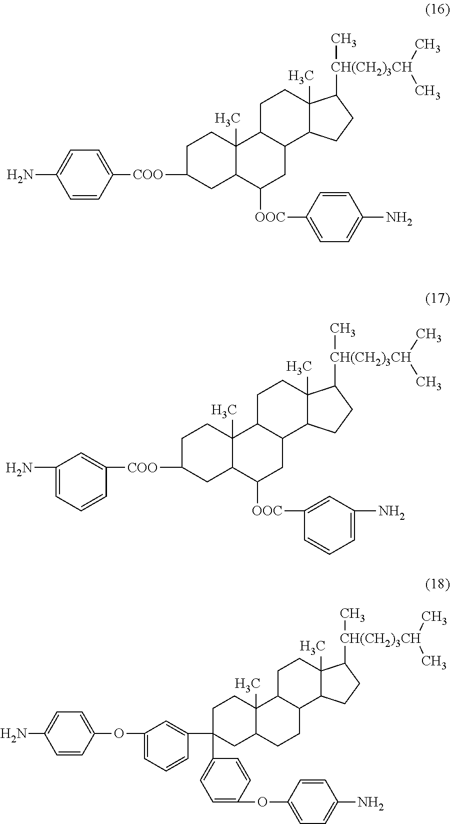

In Formula (9) above, R⁶ may be randomly selected from alkyls having 1 to 20 carbon atoms and may be linear or branched. Further, one —CH₂— may be substituted with —O—. Specific examples include methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, isopropyl, isobutyl, sec-butyl, t-butyl, isopentyl, neopentyl, t-pentyl, 1-methylpentyl, 2-methylpentyl, 3-methylpentyl, 4-methylpentyl, isohexyl, 1-ethylpentyl, 2-ethylpentyl, 3-ethylpentyl, 4-ethylpentyl, 2,4-dimethylhexyl, 2,3,5-triethylheptylmethoxy, ethoxy, propyloxy, butyloxy, pentyloxy, hexyloxy, methoxymethyl, methoxyethyl, methoxypropyl, methoxybutyl, methoxypentyl, methoxyhexyl, ethoxymethyl, ethoxyethyl, ethoxypropyl, ethoxybutyl, ethoxypentyl, ethoxyhexyl, hexyloxymethyl, hexyloxyethyl, hexyloxypropyl, hexyloxybutyl, hexyloxylpentyl, and hexyloxyhexyl. The preferred among them are propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, and eicosyl.

Further, in Formula (9) above, B¹, B², and B³ can be selected, independently from one another, from a single bond and 1,2-ethylene, but it is preferred that the number of 1,2-ethylene in Formula (9) above be 0 or 1.

Examples of especially preferred compounds in Formula (9) above have combinations of R⁶, A¹, A², A³, A⁴, B¹, B², and B³ shown by way of example in Tables 1 to 3 below. In the tables, B is 1,4-phenylene, Ch is 1,4-cyclohexylene, — is a single bond, and E is 1,2-ethylene. Cis/trans isomers of 1,4-cyclohexylene may be mixed, but the trans isomer is preferred.

TABLE 1

| No. | R⁶ | A¹ | A² | A³ | A⁴ | B¹ | B² | B³ |
|---|---|---|---|---|---|---|---|---|
| 1 | Me | Ch | Ch | B | — | — | — | — |
| 2 | n-C₃H₇ | Ch | Ch | B | — | — | — | — |
| 3 | n-C₅H₁₁ | Ch | Ch | B | — | — | — | — |
| 4 | n-C₇H₁₅ | Ch | Ch | B | — | — | — | — |
| 5 | n-C₁₂H₂₅ | Ch | Ch | B | — | — | — | — |
| 6 | n-C₁₆H₃₂ | Ch | Ch | B | — | — | — | — |
| 7 | n-C₂₀H₄₁ | Ch | Ch | B | — | — | — | — |
| 8 | n-C₃H₇ | Ch | Ch | B | — | E | — | — |
| 9 | n-C₅H₁₁ | Ch | Ch | B | — | E | — | — |
| 10 | n-C₇H₁₅ | Ch | Ch | B | — | E | — | — |
| 11 | n-C₁₂H₂₅ | Ch | Ch | B | — | E | — | — |
| 12 | n-C₁₅H₃₁ | Ch | Ch | B | — | E | — | — |
| 13 | n-C₁₉H₃₉ | Ch | Ch | B | — | E | — | — |
| 14 | n-C₃H₇ | Ch | Ch | B | — | — | E | — |
| 15 | n-C₅H₁₁ | Ch | Ch | B | — | — | E | — |
| 16 | n-C₇H₁₅ | Ch | Ch | B | — | — | E | — |
| 17 | n-C₁₂H₂₅ | Ch | Ch | B | — | — | E | — |
| 18 | n-C₁₄H₂₉ | Ch | Ch | B | — | — | E | — |
| 19 | n-C₈H₁₈O | Ch | Ch | B | — | — | — | — |
| 20 | n-C₁₆H₃₂O | Ch | Ch | B | — | — | — | — |
| 21 | n-C₁₂H₂₅O | Ch | Ch | B | — | E | — | — |
| 22 | n-C₅H₁₁ | Ch | B | Ch | — | — | — | — |
| 23 | n-C₇H₁₅ | Ch | B | Ch | — | — | — | — |
| 24 | n-C₁₂H₂₅ | Ch | B | Ch | — | — | — | — |

TABLE 2

| No. | R⁶ | A¹ | A² | A³ | A⁴ | B¹ | B² | B³ |
|---|---|---|---|---|---|---|---|---|
| 25 | n-C₅H₁₁ | B | Ch | Ch | — | — | — | — |
| 26 | n-C₇H₁₅ | B | Ch | Ch | — | — | — | — |
| 27 | n-C₁₂H₂₅ | B | Ch | Ch | — | — | — | — |
| 28 | n-C₂₀H₄₁ | B | Ch | Ch | — | — | — | — |
| 29 | n-C₃H₇ | B | Ch | Ch | — | E | — | — |
| 30 | n-C₇H₁₅ | B | Ch | Ch | — | E | — | — |
| 31 | n-C₅H₁₁ | B | Ch | Ch | — | — | E | — |
| 32 | n-C₁₈H₃₇ | B | Ch | Ch | — | — | E | — |
| 33 | n-C₅H₁₁ | Ch | B | B | — | — | — | — |
| 34 | n-C₇H₁₅ | Ch | B | B | — | — | — | — |
| 35 | n-C₁₂H₂₅ | Ch | B | B | — | — | — | — |
| 36 | n-C₁₆H₃₂ | Ch | B | B | — | — | — | — |
| 37 | n-C₂₀H₄₁ | Ch | B | B | — | — | — | — |
| 38 | n-C₅H₁₁ | Ch | B | B | — | E | — | — |
| 39 | n-C₇H₁₅ | Ch | B | B | — | E | — | — |
| 40 | n-C₃H₇ | B | B | Ch | — | — | — | — |
| 41 | n-C₇H₁₅ | B | B | Ch | — | — | — | — |
| 42 | n-C₁₂H₂₅ | B | B | Ch | — | — | — | — |
| 43 | n-C₅H₁₁ | B | B | B | — | — | — | — |
| 44 | n-C₇H₁₅ | B | B | B | — | — | — | — |
| 45 | n-C₅H₁₁ | Ch | Ch | Ch | B | — | — | — |
| 46 | n-C₇H₁₅ | Ch | Ch | Ch | B | — | — | — |
| 47 | n-C₁₂H₂₅ | Ch | Ch | Ch | B | — | — | — |
| 48 | n-C₃H₇ | Ch | Ch | B | B | — | — | — |

TABLE 3

| No. | R⁶ | A¹ | A² | A³ | A⁴ | B¹ | B² | B³ |
|---|---|---|---|---|---|---|---|---|
| 49 | n-C₅H₁₁ | Ch | Ch | B | B | — | — | — |
| 50 | n-C₇H₁₅ | Ch | Ch | B | B | — | — | — |
| 51 | n-C₁₄H₂₉ | Ch | Ch | B | B | — | — | — |
| 52 | n-C₂₀H₄₁ | Ch | Ch | B | B | — | — | — |
| 53 | n-C₃H₇ | Ch | Ch | B | B | E | — | — |
| 54 | n-C₇H₁₅ | Ch | Ch | B | B | E | — | — |
| 55 | n-C₁₂H₂₅ | Ch | Ch | B | B | E | — | — |
| 56 | n-C₃H₇ | Ch | Ch | B | B | — | E | — |
| 57 | n-C₅H₁₁ | Ch | Ch | B | B | — | E | — |
| 58 | n-C₇H₁₅ | Ch | Ch | B | B | — | E | — |
| 59 | n-C₇H₁₅ | B | B | Ch | Ch | — | — | — |
| 60 | n-C₁₄H₂₉ | B | B | Ch | Ch | — | — | — |
| 61 | n-C₂₀H₄₁ | B | B | Ch | Ch | — | — | — |
| 62 | n-C₅H₁₁ | B | B | Ch | Ch | — | E | — |
| 63 | n-C₇H₁₅ | B | B | Ch | Ch | — | E | — |
| 64 | n-C₇H₁₅ | B | B | Ch | Ch | — | — | E |
| 65 | n-C₁₄H₂₉ | B | B | Ch | Ch | — | — | E |
| 66 | n-C₅H₁₁ | B | Ch | Ch | Ch | — | — | — |
| 67 | n-C₇H₁₅ | B | Ch | Ch | Ch | — | — | — |
| 68 | n-C₅H₁₁ | Ch | B | B | B | — | — | — |
| 69 | n-C₇H₁₅ | Ch | B | B | B | — | — | — |

The preferred specific examples of diamines having the group represented by Formula (9) above include diamines represented by Formula (19) below.

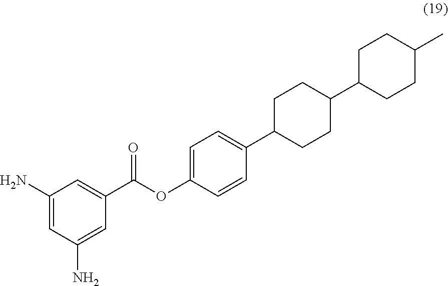

Thus, the second structural unit preferably has a side chain having a steroid skeleton or a side chain having a structure in which 3-4 rings selected from 1,4-cyclohexylene and 1,4-phenylene are linearly bonded directly or via 1,2-ethylene. As a result, the liquid crystal display device according to the present invention can be effectively driven in the VATN mode, and the average pretilt angle of the liquid crystal layer can be stabilized at 87 to 89.5° (more preferably 87.5 to 89°), which is advantageous for the VATN mode. Further, the inhibition of the AC image sticking is also effective.

Components that have been conventionally used for improving electric characteristics of alignment layers may be used as monomer components of the non-aligning diamine unit, and the preferred specific examples thereof include aromatic diamines such as p-phenylenediamine, 1,4-bis(4-aminophenyl)benzene, 4,4′-diaminobiphenyl, 3,3′-dimethyl-4,4′-diaminobiphenyl, 3,3′-dimethoxy-4,4′-diaminobiphenyl, 3,3′-dihydroxy-4,4′-diaminobiphenyl, 3,3′-dichloro-4,4′-diaminobiphenyl, 3,3′-dicarboxy-4,4′-diaminobiphenyl, 4,4′-bis(4-aminophenoxy)biphenyl, 4,4′-diaminodiphenylmethane, diaminodiphenylether, 2,2-diaminodiphenylpropane, 4,4′-diaminodiphenylsulfone, diaminobenzophenone, 1,3-bis(4-aminophenoxy)benzene, 1,4-bis(4-aminophenoxy)benzene, 4,4′-di(4-aminophenoxy)diphenylsulfone, 2,2-bis[4-(4-aminophenoxy)phenyl]propane, and 1,1,1,3,3,3-hexafluoro-2,2-bis[4-(4-aminophenoxy)phenyl]propane, alicyclic diamines such as diaminodicyclohexylmethane, diaminodicyclohexylether, and diaminocyclohexane, and aliphatic diamines such as 1,2-diaminoethane, 1,3-diaminopropane, 1,4-diaminobutane, and 1,6-diaminohexane. These diamines may be used individually or in combinations of two or more thereof.

The preferred examples of acid anhydrides that can be used for the first constituent materials include acid anhydride (PMDA) represented by Formula (20) below, acid anhydride (CBDA) represented by Formula (21) below, acid anhydride (BPDA) represented by Formula (22) below, acid anhydride (exoHDA) represented by Formula (23) below, acid anhydride (BTDA) represented by Formula (24) below, acid anhydride (TCA) represented by Formula (25) below, and acid anhydride (NDA) represented by Formula (26) below. These acid anhydrides may be used individually or in combinations of two or more thereof.

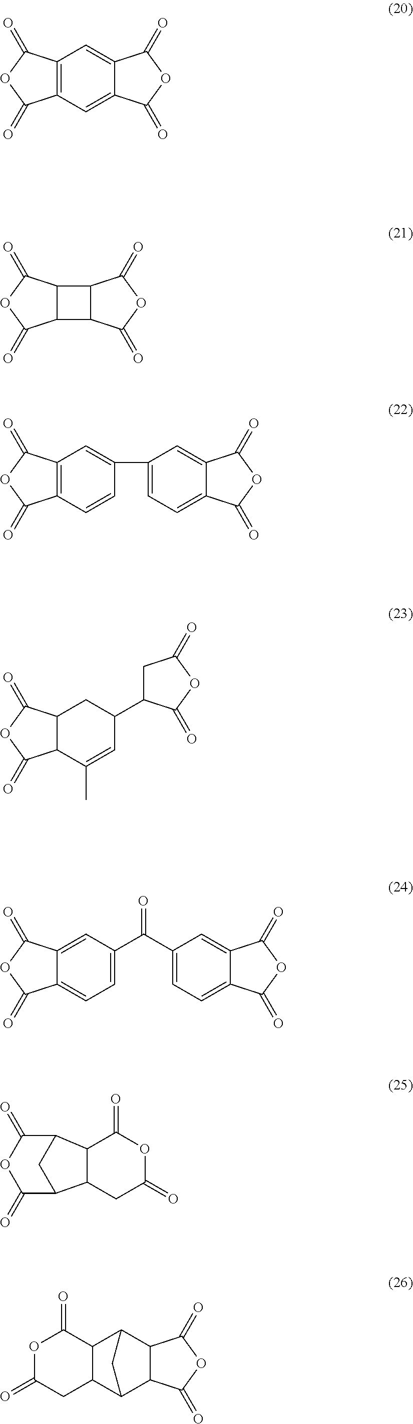

Meanwhile, the first constituent material may be a polyamide, a polyamidoimide, and a polysiloxane. Thus, the first constituent material may have a main chain structure of a polyamide. In this case, the first constituent material can be formed by polymerization of the above-described first structural unit and second structural unit and a dicarboxylic acid. Further, the first constituent material may have a main chain structure of a polysiloxane, that is, a main chain structure including a siloxane bond (≡Si—O—Si≡).

The first constituent material may be also constituted by a first structural unit having a photofunctional group including a decomposition reaction under light irradiation, and from the standpoint of inhibiting the spread in pretilt angle, it is preferred that the first structural unit have a photofunctional group inducing a crosslinking reaction (inclusive of a dimerization reaction), an isomerization reaction, photorealignment, or a combined reaction thereof under light irradiation as mentioned hereinabove. Examples of the alignment layer materials (first constituent materials) causing a photodecomposition reaction (a decomposition reaction induced by light) and providing a liquid crystal with pretilt include polyvinyl alcohol, polyamides, and polyimides.

(2-2. Second Constituent Material)

The second constituent material is not particularly limited, provided it is a polymer that is at least partially imidized and has no property of controlling the alignment of liquid crystal molecules. For example, polyimides (may be partial polyimides) other than the polyimides that are generally used for controlling the alignment of liquid crystal molecules can be used as appropriate.

More specifically, diamines that have been conventionally used for improving electric characteristics of alignment layers may be used for the second constituent material. Examples of such diamines include aromatic diamines such as p-phenylenediamine, 1,4-bis(4-aminophenyl)benzene, 4,4′-diaminobiphenyl, 3,3′-dimethyl-4,4′-diaminobiphenyl, 3,3′-dimethoxy-4,4′-diaminobiphenyl, 3,3′-dihydroxy-4,4′-diaminobiphenyl, 3,3′-dichloro-4,4′-diaminobiphenyl, 3,3′-dicarboxy-4,4′-diaminobiphenyl, 4,4′-bis(4-aminophenoxy)biphenyl, 4,4′-diaminodiphenylmethane, diaminodiphenylether, 2,2-diaminodiphenylpropane, 4,4′-diaminodiphenylsulfone, diaminobenzophenone, 1,3-bis(4-aminophenoxy)benzene, 1,4-bis(4-aminophenoxy)benzene, 4,4′-di(4-aminophenoxy)diphenylsulfone, 2,2-bis[4-(4-aminophenoxy)phenyl]propane, and 1,1,1,3,3,3-hexafluoro-2,2-bis[4-(4-aminophenoxy)phenyl]propane, alicyclic diamines such as diaminodicyclohexylmethane, diaminodicyclohexylether, and diaminocyclohexane, and aliphatic diamines such as 1,2-diaminoethane, 1,3-diaminopropane, 1,4-diaminobutane, and 1,6-diaminohexane. These diamines may be used individually or in combinations of two or more thereof.

Acid anhydrides represented by Formulas (20) to (26) above are preferred as the acid anhydride to be used in the second constituent material. These acid anhydrides may be used individually or in combinations of two or more thereof.

(2-3. Improvement Mechanism of Voltage Retention Ratio and Residual DC)

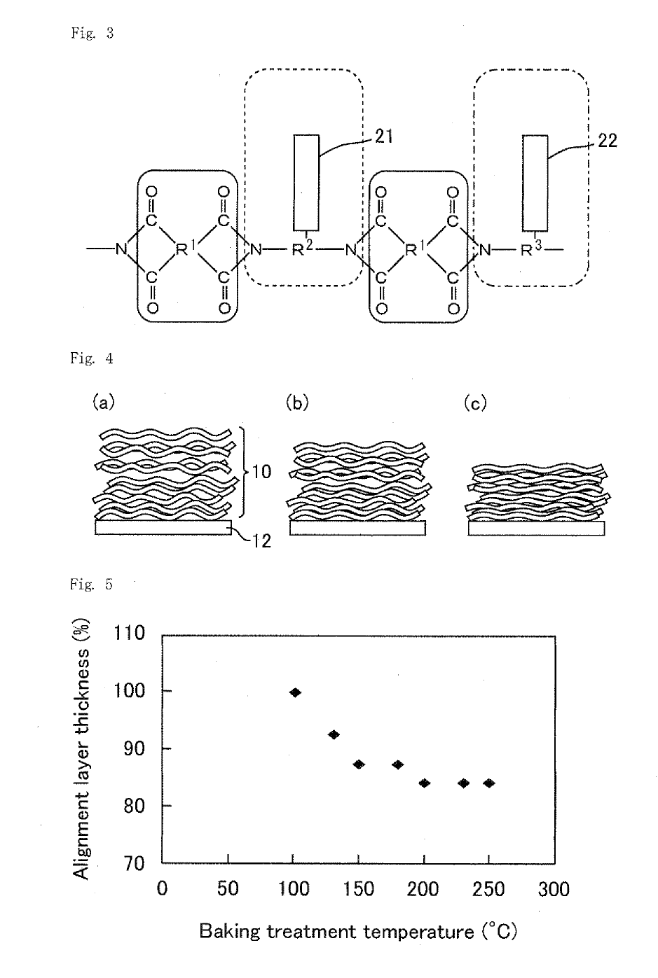

The reasons for the improvement of voltage retention ratio and residual DC in the liquid crystal display device having an alignment layer formed from the alignment layer material according to the present embodiment will be described below with reference to FIGS. 4 and 5.

The degradation of voltage retention ratio and residual DC voltage caused by a low-temperature baking treatment can be explained in the following manner. The thickness of the alignment layer 10 decreases with the increase in baking treatment temperature, as shown in FIGS. 4(a) to 4(c). More specifically, as shown in FIG. 5, during low-temperature baking, the difference between the layer thickness before and after the baking is small. By contrast, as the baking temperature rises, the variation in layer thickness increases and the layer thickness variation amount reaches saturation at a certain temperature.

Thus, during low-temperature baking, the residual solvent is present and the imidization reaction of the polyamic acid practically does not occur. By contrast, as the baking temperature is raised, the amount of residual solvent decreases and the imidization reaction induced by heat proceeds. In addition the layer density increases. Thus, heating causes thermal packing and a more tightened state of the alignment layer is assumed. As a result, elution of impurities from inside the layer is unlikely to occur. Conversely, a state can be assumed in which the impurities present inside the display device (for example, the liquid crystal layer) are more unlikely to be adsorbed. To look at the matter from a different angle, during low-temperature baking, the residual solvent is present, the layer is in a less dense state, and the enclosed impurities are easily released inside the display device (for example, the liquid crystal layer). As a result, the voltage retention ratio is degraded. Further, since the layer is not dense, the surface area to which the impurities present inside the display device (for example, the liquid crystal layer) can adhere is increased and the impurities can penetrate deep into the layer. As a result, the impurities that have adhered require a long time to be released from the alignment layer. As a result, the residual DC voltage is degraded.

The inventors have discovered that the above-mentioned problem can be resolved by imidizing the constituent material of the alignment layer in advance. Subsequent research demonstrated that when the alignment layer material capable of controlling the alignment under light irradiation is imidized with the abovementioned object, the image sticking caused by the residual DC can be inhibited, but the AC image sticking can worsen.

The alignment layer has heretofore been sometimes subjected to a treatment called modification treatment, two-layer formation treatment, or hybridization treatment (see, for example, Patent Documents 1 and 2). The residual DC increases with the increase in thickness (volume) of the alignment layer. Therefore, the residual DC decreases with the decrease in thickness (volume) of the alignment layer. By contrast, in order to prevent coating defects in the alignment layer printing process in panel production, a certain thickness of the alignment layer, for example, thickness of equal to or greater than 60 nm, should be maintained. A method called the modification treatment, two-layer formation treatment, or hybridization treatment is used to resolve this problem. More specifically, the substrate is coated with a varnish obtained by blending a polymer capable of controlling the alignment of liquid crystal and a polymer for improving electric characteristics at a predetermined ratio (for example, 50:50 to 5:95). In the varnish, phase separation between the polymers occurs immediately after the varnish is coated or in the baking process. By using this effect, it is possible to form a layer of the polymer improving electric characteristics on the substrate side and form the liquid crystal alignment layer on the liquid crystal layer side. As a result, the thickness of the alignment control layer exposed on the liquid crystal layer side decreases, and the decrease in the residual DC and image sticking caused by the residual DC can be expected. However, with such a method, sufficient improvement of electric characteristics and inhibition of image sticking cannot be demonstrated if a low baking temperature is set.

This time, it has been discovered that a high imidization ratio can be realized, even during low-temperature baking, by imidizing in advance a polymer portion that improves electric characteristics, without controlling the alignment of liquid crystal in the treatment called modification treatment, two-layer formation treatment, or hybridization treatment. As a result, it is possible to obtain a liquid crystal display device which has a high voltage retention ratio that cannot be attained in the conventional material when the baking temperature is low and also in which the image sticking caused by the residual DC is unlikely to occur. In addition, the deterioration of AC sticking can be also inhibited even though the process of baking the alignment layer is performed at a low temperature.

The liquid crystal display device according to the present embodiment can be used not only in the VATN mode, but also in the applications of a horizontal alignment type such as a TN mode, an ECB mode, and an IPS mode. In this case, the AC image sticking can be inhibited, for example, by forming a horizontal alignment layer (horizontal photoalignment layer) including a copolymer of an imide or amide derivative having a photofunctional group and an imide or amide derivative having no photofunctional group.

(3. Method for Fabricating the Alignment Layer)

A method for fabricating the alignment layer according to the present embodiment will be described below.

First, a monomer component of the first structural unit and an acid anhydride are polymerized (copolymerized) by the conventional well-known method and a first constituent material is synthesized. In this case, it is preferred that the monomer component of the second structural unit be added. Likewise, a diamine and an acid anhydride are polymerized (copolymerized) by the conventional well-known method and a polyamic acid (polyimide precursor) for the second constituent material is synthesized.

The second constituent material is then fabricated by imidization of the polyimide precursor for the second constituent material that is performed by the conventional well-known method (for example, a method based on heating or a chemical method using a catalyst). If necessary, the first constituent material is also imidized within a range that is not beyond imidization of the second constituent material. The imidization ratio can be adjusted by changing the reaction temperature and reaction time as appropriate.

The first constituent material and the second constituent material are then purified.

A varnish for coating (printing) the first constituent material and second constituent material on the substrate is then prepared. A mixed solvent including solvents such as γ-butyrolactone (BL), N-methylpyrrolidone (NMP), butyl cellosolve (BC), diethylether dibutyl glycol (DEDG), diisobutyl ketone (DISK), and dipentyl ether (DPE) is preferred as a solvent to be included in the varnish.

The varnish including the first constituent material and second constituent material is then coated on the substrate. A spin coating method, a flexo printing method, and an ink jet printing method are preferred for coating the varnish.

After the varnish has been printed, pre-baking is performed for 0.5 to 10 min at 50 to 120° C. on a hot plate for pre-baking and then main baking is performed on a hot plate for main baking. The heating temperature and heating time in pre-baking and main baking can be set as appropriate, but according to the present embodiment, the main baking can be performed at a temperature lower than that in the conventional process.

More specifically, the temperature of main baking is 80 to 270° C. (more preferably 100 to 250° C., even more preferably 120 to 230° C.). Where the temperature of main baking is less than 80° C., the solvent can remain. Where the temperature of main baking is higher than 270° C., the alignment film can become yellow and brittle.

After the coating process and/or in the baking process, layer separation occurs between the first constituent material and second constituent material, thereby producing the upper layer formed by the first constituent material and the lower layer formed by the second constituent material. When subjected to aligning treatment by light irradiation, the upper layer becomes a vertical photoalignment layer (first constituent portion), and the lower layer becomes an electric characteristic improving layer (second constituent portion).

Layer separation of the first constituent material and second constituent material occurs due to the difference in polarity between the first constituent material and second constituent material or difference in affinity for the substrate and/or air between the first constituent material and second constituent material. Therefore, strictly speaking, the vertical photoalignment layer (first constituent portion) is formed not only by the first constituent material and may include the second constituent material. Further, strictly speaking the electric characteristic improving layer (second constituent portion) is formed not only by the second constituent material and may include the first constituent material. Thus, after the coating process and/or in the baking process, at least the first constituent material may appear on the layer surface and the first constituent material and second constituent material may not be completely separated into two layers.

Further, the alignment layer may be also fabricated by coating on the substrate the first varnish that includes the second constituent material and no first constituent material, baking to form the first film, then coating the second varnish that includes the first constituent material and no second constituent material on the substrate where the first film has been formed, and baking to form the second film. In this case, it is also possible to form a stacked structure including an electric characteristic improving layer (second constituent portion) composed of the first film, which is the lower layer, and a vertical photoalignment layer (first constituent portion) composed of the second film, which is the upper layer.

The alignment layer formed on the substrate is subjected to aligning treatment by light irradiation. The irradiation conditions of the alignment layer can be set as appropriate, but it is preferred that the light used for irradiating (exposing) the alignment layer include ultraviolet radiation (more preferably, polarized ultraviolet radiation), more preferably be ultraviolet radiation (more preferably, polarized ultraviolet radiation). From the standpoint of shortening the tact time in the manufacturing process, it is preferred that the exposure energy of light irradiation be equal to or less than 100 mJ/cm², more preferably equal to or less than 50 mJ/cm², and even more preferably equal to or less than 20 mJ/cm² when the divided alignment treatment is performed by dividing the inside of each pixel for exposure with a light-blocking mask (photomask). Other irradiation conditions (for example, whether polarization is used and irradiation angle) can be set as appropriate.

In the technique described in Patent Document 3, the irradiation dose of polarized ultraviolet irradiation is high (for example, 30 J/cm²), but in the liquid crystal display device according to the present embodiment, the irradiation dose can be made lower (for example, about 20 mJ/cm²). This is because the technique described in Patent Document 3 uses an alignment layer material of a photodecomposition type, whereas in the liquid crystal display device according to the present embodiment, a material of a photo-crosslinking type (material having a photofunctional group that induces a crosslinking reaction under light irradiation) that can reduce the irradiation dose can be advantageously used as the first constituent material.

The alignment layer according to the present embodiment is formed and subjected to aligning treatment in the above-described manner. As a result, the alignment layer according to the present embodiment, in particular the photoalignment layer, has a structure derived from photofunctional groups (preferably, at least one structure selected from the group consisting of a bonded structure, a photoisomerized structure, and a photorealignment structure of photofunctional groups), and substantially uniform pretilt angle is generated in the alignment layer plane.

(4. Basic Operation of the Liquid Crystal Display Device)

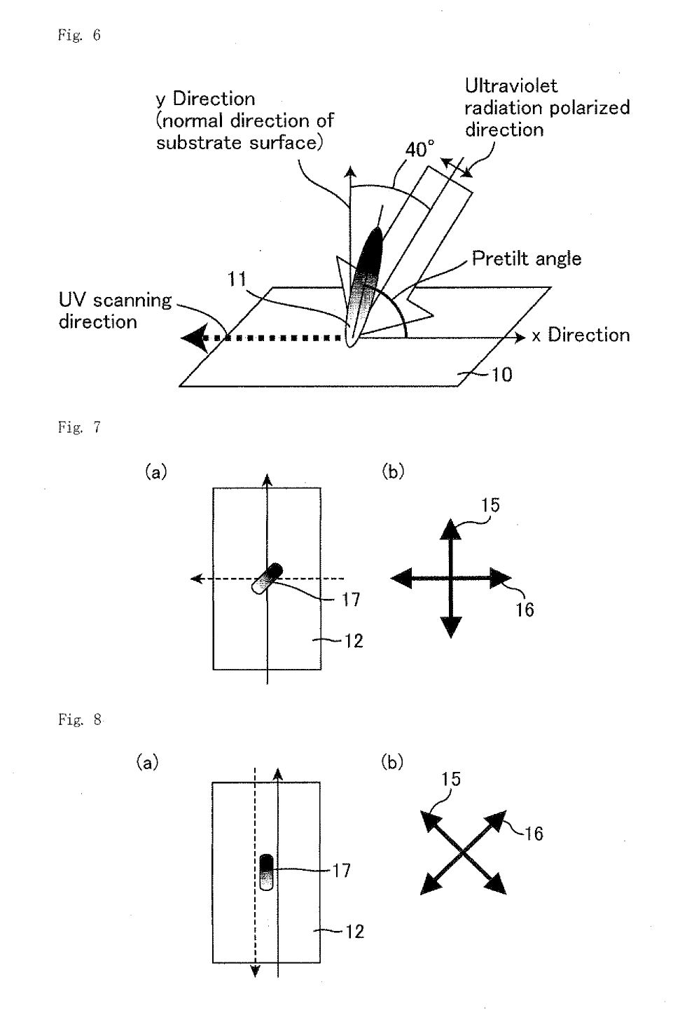

The basic operation (operation principle) of the liquid crystal display device according to the present embodiment will be described below with reference to FIGS. 6 to 11.

Where the alignment layer 10 according to the present embodiment is irradiated, for example, obliquely at an angle of 40° from the normal direction of the substrate surface with ultraviolet radiation polarized parallel to the incidence plane (UV radiation, shown by a white arrow in FIG. 6) as shown in FIG. 6, a pretilt angle of the liquid crystal molecule 11 can be generated on the UV irradiation direction side, as shown in FIG. 6. The exposure of the alignment layer 10 can be performed by one-shot exposure or scanning exposure. Thus, the alignment layer 10 may be exposed in a state in which the substrate and the light source are fixed, or the alignment layer 10 may be exposed, while scanning the UV radiation along the UV scanning direction as shown by a dot-line arrow in FIG. 6.

In the liquid crystal display device according to the present embodiment, as shown in FIG. 7(a), the exposure of the alignment layer and joining of the substrates may be performed so that the directions at which the pair of substrates (upper and lower substrates 12) is irradiated with light beams are substantially orthogonal, in the plan view of the substrates. Further, the pretilt angles of liquid crystal molecules in the vicinity of the alignment layers provided at the upper and lower substrate 12 may be substantially equal, and a liquid crystal material that includes no chiral material may be injected in the liquid crystal layer. In this case, where an AC voltage equal to or higher than a threshold is applied between the upper and lower substrates 12, the liquid crystal molecules have a structure twisted by 90° in the normal direction of the substrates between the upper and lower substrates 12, and the average liquid crystal director direction 17 during AC voltage application is exactly between, as shown in FIG. 7, the light irradiation directions on the upper and lower substrates 12, in the plan view of the substrates. Further, as shown in FIG. 7(b), the absorption axis direction 16 of the polarizer (upper polarizer) disposed on the upper substrate side matches the photoaligning treatment direction of the upper substrate, and the absorption axis direction 15 of the polarizer (lower polarizer) disposed on the lower substrate side matches the photoaligning treatment direction of the lower substrate. Where the aligning treatment of the alignment layer and the arrangement of the polarizers are performed in the above-described manner, the liquid crystal display device according to the present embodiment has the so-called VATN mode.

Further, in the liquid crystal display device according to the present embodiment, as shown in FIG. 8(a), the exposure of the alignment layer and joining of the substrates may be performed so that the directions at which the upper and lower substrates 12 are irradiated with light beams are substantially parallel and have opposite orientations (counter parallel), in the plan view of the substrates. Further, the pretilt angles of liquid crystal molecules in the vicinity of the alignment layers provided at the upper and lower substrate 12 may be substantially equal, and a liquid crystal material that includes no chiral material may be injected in the liquid crystal layer. In this case, when no voltage is applied between the upper and lower substrates 12, the liquid crystal molecules located in the vicinity of the interfaces of the upper and lower substrates and the liquid crystal layer have a homogeneous structure with a pretilt angle of about 88.5° (homogeneous alignment), and the average liquid crystal director direction 17 during AC voltage application is along, as shown in FIG. 8(a), the light irradiation directions on the upper and lower substrates 12, in the plan view of the substrates. Further, as shown in FIG. 8(b), the absorption axis directions 15, 16 of the polarizer (upper polarizer) disposed on the upper substrate side and the polarizer (lower polarizer) disposed on the lower substrate side are shifted by 45° with respect to the photoaligning treatment directions of the upper and lower substrates, in the plan view of the substrates. Where the aligning treatment of the alignment layer and the arrangement of the polarizers are performed in the above-described manner, the liquid crystal display device according to the present embodiment has the so-called VAECB (Vertical Alignment Electrically Controlled Birefringence) mode in which the photoaligning treatment directions are counter parallel between the upper and lower substrates and the liquid crystal molecules are aligned vertically. In FIG. 8, the solid-line arrow shows the light irradiation direction (photoaligning treatment direction) of the lower substrate and the dotted-line arrow shows the light irradiation direction (photoaligning treatment direction) of the upper substrate.

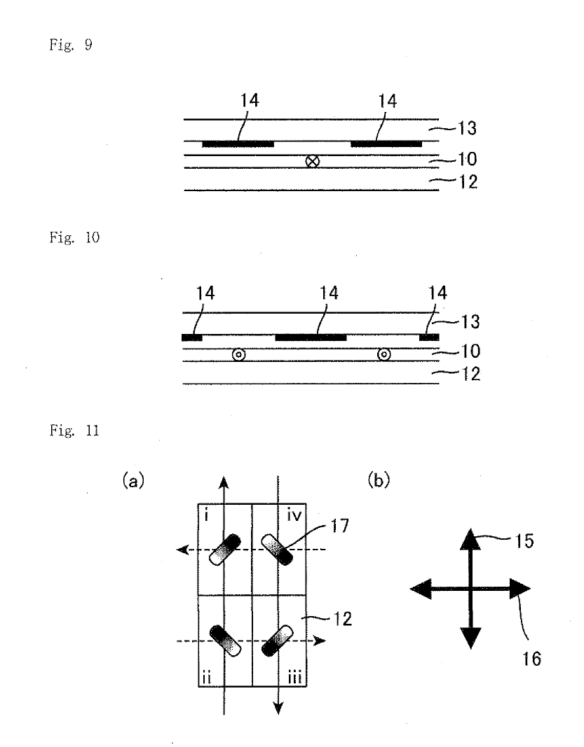

The case in which pixels in the liquid crystal display device according to the present embodiment have been subjected to domain division as shown in FIG. 11 will be explained below. In the exposure process for forming four domains in the liquid crystal display device according to the present embodiment, first, as shown in FIG. 9, a region corresponding to half of a pixel (or a sub-pixel) is exposed in one direction (depthwise direction from the front of the paper sheet in FIG. 9) by using a photomask 13 having a light-blocking portion 14 of a size equal to half of a pixel (or a sub-pixel) width in the liquid crystal display device and the remaining half of the region is blocked by the light-blocking portion 14. In the next step, as shown in FIG. 10, the photomask 13 is shifted by about half-pitch of the pixel (or a sub-pixel), the exposed region is blocked by the light-blocking, portion 14, and the unblocked region (the unexposed region that has not been exposed in the step illustrated by FIG. 9) is exposed in the direction (from the depth to the front of the paper sheet in FIG. 10) opposite that of the step illustrated by FIG. 9. As a result, regions demonstrating a liquid crystal pretilt in the mutually opposite directions are formed in a stripe-like fashion so as to divide in two the width of a pixel (or a sub-pixel) of the liquid crystal display device.

As described hereinabove, each pixel (or each sub-pixel) of the substrates is subjected to domain division with an equal pitch so as to divide the pixel in two. The substrates are then arranged (joined) so that the division directions (photoaligning treatment directions) in the upper and lower substrates 12 are orthogonal to each other, in the plan view of the substrates, and a liquid crystal material containing no chiral material is injected in the liquid crystal layer. As a result, as shown in FIG. 11(a), the four divided domains can be formed in which the alignment directions of liquid crystal molecules positioned close to the center in the direction perpendicular to the liquid crystal layer are different from each other in four regions (i to iv in FIG. 11(a)), more specifically, they are substantially orthogonal to each other. Thus, the average liquid crystal director direction 17 during AC voltage application is exactly between, as shown in FIG. 11(a), the light irradiation directions on the upper and lower substrates 12, in the plan view of the substrates. Further, as shown in FIG. 11(b), the photoaligning treatment direction (dot-line arrow in FIG. 11(a)) of the upper substrate (color filter substrate) matches the absorption axis direction 16 of the polarizer disposed on the upper substrate side, and the photoaligning treatment direction (solid-line arrow in FIG. 11(a)) of the lower substrate (drive element substrate) matches the absorption axis direction 15 of the polarizer disposed on the lower substrate side.

At the boundaries between the domains, the alignment direction of liquid crystal molecules on one substrate matches the absorption axis direction of the polarizer, and the alignment direction of liquid crystal molecules on the other substrate is substantially orthogonal to the substrate. Therefore, the boundaries between the domains become dark lines that do not transmit light, even if a voltage is applied between the substrate, when the polarizers are arranged in a cross Nicol configuration.

The exposure is usually performed in a state in which the boundaries between the domains overlap, and in the overlapping exposure portions of the conventional photoalignment layers (double-exposed portions), the pretilt angle is not stabilized. Further, in the double-exposed portions of the conventional photoalignment layers, the AC image sticking tends to increase due to the asymmetrical number of exposure cycles. However, by using the alignment layer according to the present embodiment, in particular by using the first constituent material including the first structural unit and the second structural unit, it is possible to suppress effectively the occurrence of AC image sticking in the double-exposed portions and the spread in pretilt angle of liquid crystal molecules.

As described hereinabove, in the liquid crystal display device according to the present embodiment, when four domains with mutually different (substantially orthogonal) alignment directions of liquid crystal molecules are formed, an excellent viewing angle characteristic, that is, a wide viewing angle, can be realized.

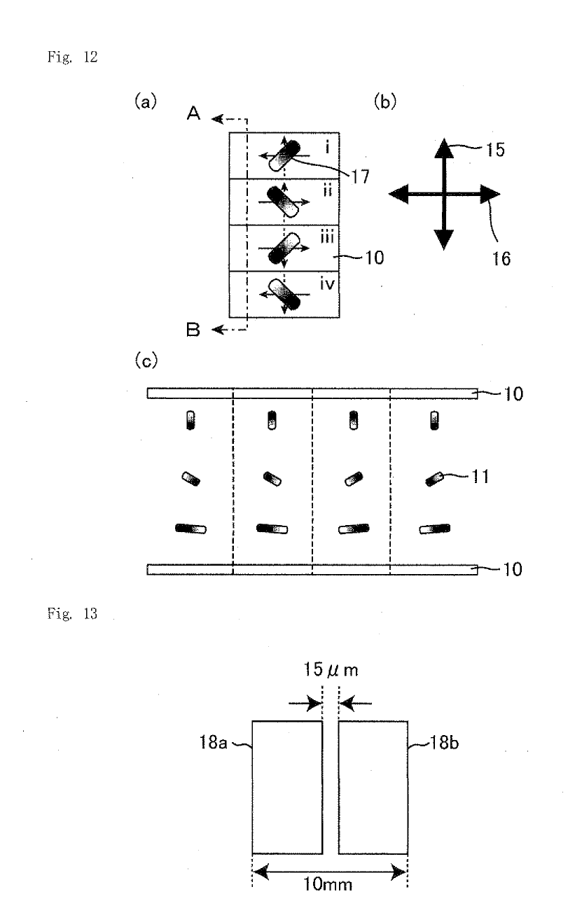

The domain layout in the liquid crystal display device according to the present embodiment is not limited to the four-domain layout such as shown in FIG. 11(a) and may be such as shown in FIG. 12(a).

This domain layout is fabricated by performing domain division with an equal pitch such that each pixel (or each sub-pixel) of the substrates is divided in two as shown in FIG. 12(a). Then, the two substrates are disposed (joined) so that the division directions (photoaligning treatment directions) are mutually orthogonal in the upper and lower substrates 12, in the plan view of the substrates, and the upper substrate (color filter substrate) is shifted by about ¼ pitch of the pixel in the direction of the dot-line arrow in FIG. 12(a). As a result, as shown in FIG. 12(a), the four divided domains can be formed in which the alignment directions of liquid crystal molecules positioned close to the center in the direction perpendicular to the liquid crystal layer are different from each other in four regions (i to iv in FIG. 12(a)), more specifically, they are substantially orthogonal to each other. Thus, the average liquid crystal director direction 17 during AC voltage application is exactly between, as shown in FIG. 12(a), the light irradiation directions on the upper and lower substrates 12, in the plan view of the substrates. Further, as shown in FIG. 12(b), the photoaligning treatment direction (solid-line arrow in FIG. 12(a)) of the upper substrate (color filter substrate) matches the absorption axis direction 16 of the polarizer disposed on the upper substrate side, and the photoaligning treatment direction (dot-line arrow in FIG. 12(a)) of the lower substrate (drive element substrate) matches the absorption axis direction 15 of the polarizer disposed on the lower substrate side. Further, when no voltage is applied between the upper and lower substrates, the liquid crystal molecules are aligned in the direction substantially orthogonal to the upper and lower substrates by the alignment control power of the alignment layer. By contrast, where a voltage equal to or higher than a threshold is applied between the upper and lower substrates, the liquid crystal molecules 11 are twisted through about 90° between the upper and lower substrates and four different alignment states are present in the four domains, as shown in FIG. 12(c).

The present invention will be described below in greater detail on the basis of examples thereof, but the present invention is not limited to these examples.

### Example 1

First, two glass substrates were prepared that had a thickness of 0.7 mm and transparent electrodes composed of ITO.

Then, a copolymer of a diamine having the above-described photofunctional group, a diamine having no photofunctional group, and an acid anhydride was synthesized, and a polyamic acid with an imidization ratio of 0% was prepared as the first constituent material.

A copolymer was then synthesized by using 2,2-dimethyl-4,4-diaminobiphenyl and an acid anhydride (CBDA) represented by Formula (21) above as monomer components and a polyimide (partial polyimide) with an imidization ratio of 45% was prepared as the second constituent material.

The first constituent material and the second constituent material taken at a ratio of the first constituent material to the second constituent material of 30 wt. %:70 wt. % were then dissolved in N-methylpyrrolidone (NMP) and an alignment layer material (varnish) was prepared. The concentration of the first constituent material and second constituent material in the alignment layer material was made 5 wt. %.

The alignment layer material was then coated by a spin coating method on the surfaces of both substrates on the transparent electrode sides thereof. Pre-baking was then performed for 1 min at a temperature of 90° C. on a hot plate for pre-baking, and main baking was then performed for 40 min at a temperature of 130° C. on a hot plate for main baking, thereby forming an alignment layer with a thickness of 100 nm. As a result, the lower layer serving as the electric characteristic improving layer (second constituent portion) and the upper layer serving as the vertical photoalignment layer (first constituent portion) were formed separately.

The two substrates were then cooled to room temperature and the photoaligning treatment was thereafter performed by irradiating (exposing) with UV radiation the alignment layer surfaces of these substrates provided with ITO electrodes. More specifically, the substrates were irradiated with P-polarized ultraviolet radiation with a polarization degree of 10:1 at an exposure energy of 20 mJ/cm² from a direction at 40° with respect to the substrate surface normal. Two substrates in which the alignment layer has been subjected to the aligning treatment were thus fabricated.

One of the substrates was coated with a sealing material, the two substrates were joined so as to leave a gap of 3.5 μm, and the sealing material was cured. An Nn liquid crystal material (MLC-6610, manufactured by Merck Co., Inc.), which has negative dielectric anisotropy, was then injected therein and sealed. The polarizers disposed in a cross Nicol configuration were then attached to the surfaces (outer surfaces) of the two substrates and a liquid crystal display element of Example 1 was fabricated.

### Example 2

A liquid crystal display element of Example 2 was fabricated by the same process as in Example 1, except that the main baking process of the alignment layer material was performed at 200° C.

### Comparative Example 1

A liquid crystal display element of Comparative Example 1 was fabricated by the same process as in Example 1, except that the second constituent material was used without imidization. Thus, in the present comparative example, a polyamic acid was used for both the material of the first constituent portion (first constituent material) and the material of the second constituent portion (second constituent material).

### Comparative Example 2

A liquid crystal display element of Comparative Example 2 was fabricated by the same process as in Comparative Example 1, except that the first constituent material was imidized in advance at a 45% ratio. Thus, in the present comparative example, a polyimide (partial polyimide) with an imidization ratio of 45% was used as the material of the first constituent portion (first constituent material) and the polyamic acid was used as the material of the second constituent portion (second constituent material).

### Comparative Example 3

A liquid crystal display element of Comparative Example 3 was fabricated by the same process as in Comparative Example 1, except that the main baking process of the alignment layer material was performed at 200° C.

Imidization Ratio in Solution State

The imidization ratio (%) in a solution state was calculated from an 1H-NMR spectrum of the solution including the polymer. More specifically, a peak close to 9 to 11 ppm was taken as a peak derived from the polyamic acid, a peak close to 7 to 9 ppm was taken as a peak derived from the polyimide, and the ratio of areas of the two peaks (integral value) was used for calculations.

Imidization Ratio in Film State

The imidization ratio (%) in a film state was calculated by the following equation from the FT-IR spectrum of the film after main baking.

Imidization Ratio(%)=[As(C—N)/As(C═C)]/[Ar(C—N)/Ar(C═C)].

Here, A(C—N) is a light absorbance of imide C—N stretching vibrations (about 1370 cm⁻¹) and A(C═C) is a light absorbance of aromatic C═C stretching vibrations (about 1500 cm⁻⁴). Further, As is a light absorbance of the sample coated film (alignment layer after main baking in the examples and comparative examples), and Ar is a light absorbance of the reference coating film. The reference coating film is an alignment layer formed by changing the main baking conditions of the sample coating film to 300° C. and 90 min. The imidization ratio of the reference coating film was assumed to be 100%.

Voltage Retention Ratio

A voltage retention ratio was measured by applying 5 V pulse waves for 60 μsec to the liquid crystal display element and then measuring the voltage retained after 16.7 msec in a state where the liquid crystal display element was heated to a temperature of 70° C. A device VHR-1 manufactured by Toyo Tech. Corp. was used for the measurements.

Residual DC

An AC voltage (rectangular wave with 3 V and 30 Hz) and a DC voltage (2V) were applied to the liquid crystal display element for 2 h at a temperature of 70° C., the DC voltage was then cut off, and the DC voltage remaining in the liquid crystal display element was then immediately measured by a flicker quenching method.

AC Image Sticking

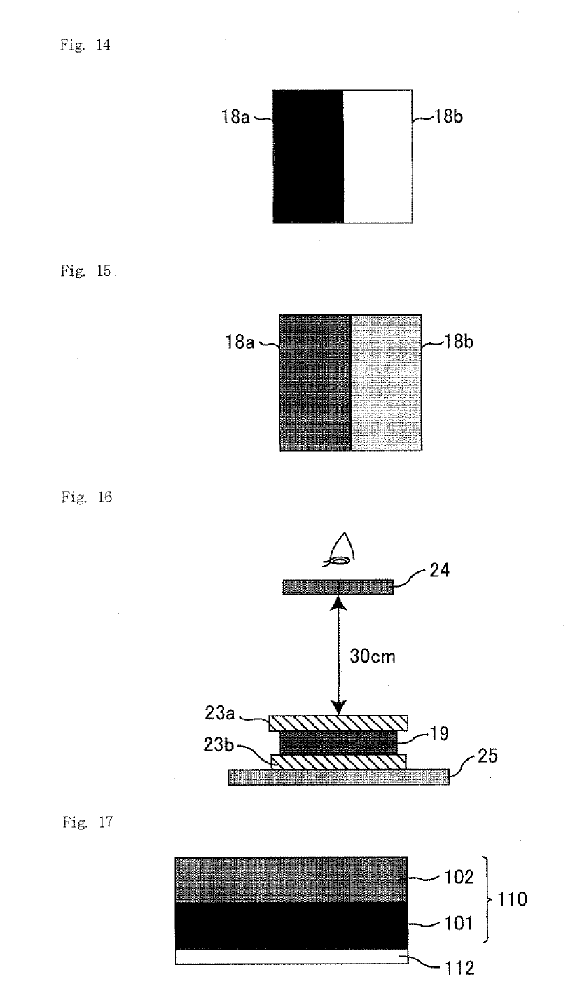

The AC image sticking was studied by using a liquid crystal display element (liquid crystal cell 19) constituted by substrates provided with ITO electrodes, as shown in FIG. 13. The substrate had formed thereon a transparent electrode divided in two electrodes (electrode 18a and electrode 18b) composed of ITO. The liquid crystal cell 19 was fabricated in the same manner as in the above-mentioned examples and comparative examples, except that the shape of the transparent electrode was different. More specifically, in the liquid crystal cell 19, the electrode 18a and electrode 18b composed of ITO were formed, as shown in FIG. 14, on one substrate, and a common electrode composed of ITO was formed on the other substrate so as to cover the electrode 18a and electrode 18b. Then, the electrode 18a of the liquid crystal cell 19 fabricated in the above-described manner was short circuited as shown in FIG. 14 and the cell was allowed to stay for 20 h in a state in which an AC voltage (30 Hz, 7 V) was applied to the electrode 18h. The same AC voltage was applied immediately thereafter to the electrode 18a and electrode 18b, as shown in FIG. 15, the cell was energized, and a difference in brightness between the electrode 18a and electrode 18b was confirmed. The confirmation was performed by sandwiching the liquid crystal cell 19 having the electrode 18a and electrode 18b between polarizers 23a, 23b arranged in a cross Nicol state, as shown in FIG. 16, placing the obtained configuration on a backlight 25, arranging a 10% ND filter (dimming filter) 24 in front of the eye, and visually evaluating the difference in brightness at a distance of 30 cm from the liquid crystal cell 19 from a front surface direction. In Table 4 below, the case in which the difference in brightness was confirmed is evaluated as “POOR”, and the case in which no difference in brightness was confirmed is evaluated as “GOOD”. The AC voltage was applied to the liquid crystal cell 19 by using a signal generator (SG-4115, manufactured by Iwatsu Test Instruments Corp.) after the cell has been allowed to stay for 20 h. The AC voltage in this case was 0 to 3 V. The AC voltage value was set within a range of 0 to 3 V when the difference in brightness was confirmed because the image sticking phenomenon is the easiest to observe within this voltage range, but the AC voltage value applied when the difference in brightness is confirmed is not limited to this voltage range.

TABLE 4

| | Imidi- | | | | Re- | |
|---|---|---|---|---|---|---|
| | zation | Imidization | | Volt- | sid- | |
| | ratio | ratio | | age | ual | |
| | of first | of second | Baking | reten- | DC | |
| | constituent | constituent | temper- | tion | volt- | AC |
| | portion | portion | ature | ratio | age | image |
| | (%) | (%) | (° C.) | (%) | (V) | sticking |
| Example 1 | 0 | 45 | 130 | 99.5 | 0.1 | Good |
| Example 2 | 0 | 45 | 200 | 99.5 | 0.0 | Good |
| Comparative | 0 | 0 | 130 | 98.6 | 0.7 | Good |
| Example 1 | | | | | | |
| Comparative | 45 | 0 | 130 | 98.6 | 0.5 | Poor |
| Example 2 | | | | | | |
| Comparative | 0 | 0 | 200 | 99.2 | 0.0 | Good |
| Example 3 | | | | | | |

As shown in Table 4, the results of Example 1 demonstrate that when the alignment layer material having the configuration in accordance with the present invention is used, a highly reliable liquid crystal cell can be obtained without degrading other display characteristics, even when the baking temperature is as low as about 130° C.

The results of Example 2 demonstrate that when the alignment layer material having the configuration in accordance with the present invention is used, a highly reliable liquid crystal cell can be obtained even at a baking temperature of 200° C.

By contrast, in Comparative Example 1, the voltage retention ratio and residual DC deteriorated, and in Comparative Example 2, the voltage retention ratio and residual DC deteriorated and the AC image sticking occurred.

The results obtained in Comparative Example 1 and Comparative Example 3 indicate that with the alignment layer of the conventional configuration, sufficient characteristics are demonstrates at a high baking temperature, but the electric characteristics are insufficient at a low baking temperature.

### Example 3

A glass substrate (TFT substrate) with a thickness of 0.7 mm that had TFT elements and transparent electrodes composed of ITO was prepared, and a glass substrate (color filter substrate) with a thickness of 0.7 mm that had a black matrix, color filters and transparent electrodes composed of ITO was also prepared.

Then, a copolymer of a diamine having the above-described photofunctional group, a diamine having no photofunctional group, and an acid anhydride was synthesized, and a polyamic acid with an imidization ratio of 0% was prepared as the first constituent material.

A copolymer was then synthesized by using 2,2-dimethyl-4,4-diaminobiphenyl and an acid anhydride (CBDA) represented by Formula (21) above as monomer components and a polyimide (partial polyimide) with an imidization ratio of 45% was prepared as the second constituent material.

The first constituent material and the second constituent material taken at a ratio of the first constituent material to the second constituent material of 30 wt. %:70 wt. % were then dissolved in N-methylpyrrolidone (NMP) and an alignment layer material (varnish) was prepared. The concentration of the first constituent material and second constituent material in the alignment layer material was made 5 wt. %.

The alignment layer material was then coated by a spin coating method on the surfaces of both substrates on the transparent electrode sides thereof. Pre-baking was then performed for 1 min at a temperature of 90° C. on a hot plate for pre-baking, and main baking was then performed for 40 min at a temperature of 130° C. on a hot plate for main baking, thereby forming an alignment layer with a thickness of 100 nm. As a result, the lower layer serving as the electric characteristic improving layer (second constituent portion) and the upper layer serving as the vertical photoalignment layer (first constituent portion) are formed separately.

The two substrates were then cooled to room temperature and the photoaligning treatment was thereafter performed by irradiating (exposing) with UV radiation the alignment layer surfaces of these substrates provided with ITO electrodes. More specifically, the substrates were irradiated with P-polarized ultraviolet radiation with a polarization degree of 10:1 at an exposure energy of 20 mJ/cm² from a direction at 40° with respect to the substrate surface normal. The photoaligning treatment was performed by the method explained with reference to FIGS. 9 to 11. Thus, the photoaligning treatment was performed to form four domains such as shown in FIG. 11. Two substrates in which the alignment layer has been subjected to the aligning treatment were thus fabricated.

One of the substrates was coated with a sealing material, the two substrates were joined so as to leave a gap of 3.5 μm, and the sealing material was cured. An Nn liquid crystal material (MLC-6610, manufactured by Merck Co., Inc.), which has negative dielectric anisotropy, was then injected therein and sealed. The polarizers disposed in a cross Nicol configuration were then attached to the surfaces (outer surfaces) of the two substrates and a liquid crystal display element of Example 3 was fabricated. The substrates were joined and the polarizers were attached as shown in FIG. 11.

### Comparative Example 4

A liquid crystal display element of Comparative Example 4 was fabricated by the same process as in Example 3, except that the second constituent material was used without imidization. Thus, the polyamic acid was used for both the material of the first constituent portion (first constituent material) and the material of the second constituent portion (second constituent material).

### Comparative Example 5

A liquid crystal display element of Comparative Example 5 was fabricated by the same process as in Comparative Example 4, except that the first constituent material was imidized in advance at a 45% ratio. Thus, in the present comparative example, a polyimide (partial polyimide) with an imidization ratio of 45% was used as the material of the first constituent portion (first constituent material) and the polyamic acid was used as the material of the second constituent portion (second constituent material).

Long-Term Energizing

The alignment and display states after long-term energizing (conditions: under 70° C., 500 h, voltage applied to liquid crystal is 7 V) were observed.

TABLE 5

| | Imidization ratio | Imidization ratio | | | |
|---|---|---|---|---|---|
| | of first | of second | | | |
| | constituent | constituent | Baking | Alignment after | Display after |
| | portion | portion | temperature | bng-term | bng-term |
| | (%) | (%) | (° C.) | operation | operation |
| Example 3 | 0 | 45 | 130 | Good | Good |
| Comparative | 0 | 0 | 130 | Good | Occurrence of |
| Example 4 | | | | | spots |
| Comparative | 45 | 0 | 130 | Poor alignment | Good |
| Example 5 | | | | | |

As shown in Table 5, the results of Example 3 indicate that when the alignment layer material having the configuration in accordance with the present invention is used, a highly reliable liquid crystal cell can be obtained without degrading other display characteristics, even when the baking temperature is as low as about 130° C.

By contrast, in Comparative Example 4, spot-like formations (spot occurrence) were observed in part of the energized region after long-term energizing. Further, in Comparative Example 5, alignment defects appeared after long-term energizing and display defects caused by reduced alignment control power appeared over the entire display region.

### Example 4

A liquid crystal display element of Example 4 was fabricated by the same process as in Example 1, except that the weight ratio of the first constituent material and the second constituent material was changed to a ratio of the first constituent material to the second constituent material of 80 wt. %:20 wt. %.

### Example 5

A liquid crystal display element of Example 5 was fabricated by the same process as in Example 1, except that the weight ratio of the first constituent material and the second constituent material was changed to a ratio of the first constituent material to the second constituent material of 50 wt. %:50 wt. %.

### Example 6

A liquid crystal display element of Example 6 was fabricated by the same process as in Example 1, except that the weight ratio of the first constituent material and the second constituent material was changed to a ratio of the first constituent material to the second constituent material of 3 wt. %:97 wt. %.

TABLE 6

| | Imidization ratio | Imidization ratio | | | | | |
|---|---|---|---|---|---|---|---|
| | of first | of second | Ratio of second | | | | |
| | constituent | constituent | constituent | Baking | Voltage | Residual DC | |
| | portion | portion | portion | temperature | retention ratio | voltage | AC image |
| | (%) | (%) | (wt. %) | (° C.) | (%) | (V) | sticking |
| Example 4 | 0 | 45 | 20 | 130 | 97.8 | 0.4 | Good |
| Example 5 | 0 | 45 | 50 | 130 | 99.3 | 0.1 | Good |
| Example 1 | 0 | 45 | 70 | 130 | 99.5 | 0.1 | Good |
| Example 6 | 0 | 45 | 97 | 130 | 99.4 | 0.2 | Poor |

As shown in Table 6, where the ratio of the second constituent material is too low, the voltage retention ratio can decrease and the residual DC can increase. Meanwhile, where the ratio of the second constituent material is too high, the AC image sticking can occur.

This application claims priority based on the Paris Convention and laws in a country where the application is entered to Japanese Patent Application No. 2009-64799 filed on Mar. 17, 2009. The content of this application is herein incorporated by reference in its entirety.

### EXPLANATION OF REFERENCE NUMERALS AND SYMBOLS

1a, 1b, 101: electric characteristic improving layers (second constituent portions)
2a, 2b: vertical photoalignment layers (first constituent portions)
10a, 10b, 10, 110: alignment layers
11: liquid crystal molecule
12a, 12b, 12, 112: substrates (upper and lower substrates)
13: photomask
14: light-blocking layer
15: absorption axis direction of polarizer disposed on lower substrate side
16: absorption axis direction of polarizer disposed on upper substrate side
17: average liquid crystal director direction during AC voltage application
18a, 18b: electrodes
19: liquid crystal display device (liquid crystal cell)
20: liquid crystal layer
21: side chain having photofunctional group
22: side chain having no photofunctional group
23a: upper polarizer
23b: lower polarizer
24: 10% ND filter (dimming filter)
25: backlight
102: alignment layer

1. A liquid crystal display device including a configuration in which a liquid crystal layer including liquid crystal molecules is sandwiched between a pair of substrates, and including an alignment layer on a surface of at least one substrate of the pair of substrates on the liquid crystal layer side thereof, wherein
the alignment layer is obtained by performing an aligning treatment by light irradiation on a layer formed using an alignment layer material including a first constituent material and a second constituent, material,
the first constituent material demonstrates a property of controlling the alignment of the liquid crystal Molecules under light irradiation,
the second constituent material is a polymer having no property of controlling the alignment of the liquid crystal molecules, and
at least part of the polymer is imidized.

2. The liquid crystal display device according to claim 1, wherein
the first constituent material is a polymer, and
an imidization ratio of the first constituent material is less than an imidization ratio of the second constituent material.

3. The liquid crystal display device according to claim 1, wherein
the first constituent material is a polymer including a side chain, and
the side chain includes a photofunctional group.

4. The liquid crystal display device according to claim 1, wherein
the alignment layer is a vertical alignment layer that controls vertical alignment of the liquid crystal molecules.

5. The liquid crystal display device according to claim 1, wherein
the alignment layer controls the alignment of the liquid crystal molecules so that an average pretilt angle of the liquid crystal layer is equal to or greater than 87°.

6. The liquid crystal display device according to claim 1, wherein
the alignment layer controls the alignment of the liquid crystal molecules so that an average pretilt angle of the liquid crystal layer is equal to or less than 89.5°.

7. The liquid crystal display device according to claim 3, wherein
the side chain includes at least one photofunctional group selected from the group consisting of a coumarine group, a cinnamate group, a chalcone group, an azobenzene group, and a stilbene group.

8. The liquid crystal display device according to claim 1, wherein
a ratio of the second constituent material to a sum total of the first constituent material and the second constituent material is equal to or greater than 40 wt. %.

9. The liquid crystal display device according to claim 1, wherein
a ratio of the second constituent material to a sum total of the first constituent material and the second constituent material is equal to or less than 95 wt. %.

10. The liquid crystal display device according to claim 1, wherein
the first constituent material appears on a surface of the at least one substrate after the alignment layer material is coated on the at least one substrate.

11. The liquid crystal display device according to claim 1, wherein
the alignment layer includes a laminated structure of an upper layer formed using the first constituent material and a lower layer formed using the second constituent material.

12. A method for manufacturing a liquid crystal display device including a configuration in which a liquid crystal layer including liquid crystal molecules is sandwiched between a pair of substrates, and including an alignment layer on a surface of at least one substrate of the pair of substrates on the liquid crystal layer side thereof, the method comprising the steps of:
forming a layer on the at least one substrate by using an alignment layer material including a first constituent material and a second constituent material; and
forming the alignment layer by performing an aligning treatment on the layer by light irradiation, wherein
the first constituent material demonstrates a property of controlling the alignment of the liquid crystal molecules under light irradiation,
the second constituent material is a polymer having no property of controlling the alignment of the liquid crystal molecules, and
at least part of the polymer is imidized.
